(19) United States
(12) Patent Application Publication
(10) Pub. No.: US 2026/0096313 A1
(43) Pub. Date: Apr. 2, 2026

(54) DISPLAY PANEL AND ELECTRONIC APPARATUS INCLUDING THE SAME

(71) Applicant: Samsung Display Co., Ltd., Yongin-si (KR)

(72) Inventors: Taegyun Kim, Yongin-si (KR); Jihyun Ka, Yongin-si (KR); Wansu Kim, Yongin-si (KR); Jaedu Noh, Yongin-si (KR); Taehyoung No, Yongin-si (KR); Daeyoon Yoo, Yongin-si (KR); Yongjun Jo, Yongin-si (KR)

(21) Appl. No.: 19/250,895

(22) Filed: Jun. 26, 2025

(30) Foreign Application Priority Data
Sep. 27, 2024 (KR) 10-2024-0132010

(51) Int. Cl. H10K 59/131; H10K 59/126

(52) U.S. Cl. CPC H10K 59/131; H10K 59/126

(57) ABSTRACT

A display panel includes a substrate; a pixel circuit including a first sub-pixel circuit, a second sub-pixel circuit, and a third sub-pixel circuit; a first insulating layer disposed on the pixel circuit; a first conductive layer disposed on the first insulating layer and including a first data line, a second data line, and a third data line; a second insulating layer disposed on the first conductive layer; and a second conductive layer disposed on the second insulating layer and including a first pixel electrode, a second pixel electrode, a third pixel electrode, and a shielding pattern. The shielding pattern includes a first portion overlapping the first data line, a second portion overlapping the second data line, and a first connection portion connecting the first portion and the second portion to each other.

This application claims priority to Korean Patent Application No. 10-2024-0132010, filed on Sep. 27, 2024, and all the benefits accruing therefrom under 35 U.S.C. § 119, the content of which in its entirety is herein incorporated by reference.

### BACKGROUND

### 1. Field

One or more embodiments relate to a display panel and an electronic apparatus including the same.

### 2. Description of the Related Art

Recently, display panels have been used in electronic apparatuses of various purposes. As display panels become more widely used, the demand for high-quality display panels has increased. To manufacture high-quality display panels, electronic elements of various configurations is desirable to be disposed in a narrow region.

### SUMMARY

As electronic elements of various configurations are disposed in a narrow region, the quality of images displayed by display panels may be deteriorated by coupling between adjacent electronic elements. However, such a technical issue is just an example, and the disclosure is not limited thereto.

Additional aspects will be set forth in part in the description which follows and, in part, will be apparent from the description, or may be learned by practice of the presented embodiments of the disclosure.

According to one or more embodiments, a display panel includes a substrate including a display area and a peripheral area outside the display area, a pixel circuit disposed in the display area and including a first sub-pixel circuit, a second sub-pixel circuit, and a third sub-pixel circuit adjacent to each other in a first direction, a first insulating layer disposed on the pixel circuit, a first conductive layer disposed on the first insulating layer and including a first data line connected to the first sub-pixel circuit, a second data line connected to the second sub-pixel circuit, and a third data line connected to the third sub-pixel circuit, a second insulating layer disposed on the first conductive layer, and a second conductive layer disposed on the second insulating layer and including a first pixel electrode connected to the first sub-pixel circuit, a second pixel electrode connected to the second sub-pixel circuit, a third pixel electrode connected to the third sub-pixel circuit, and a shielding pattern, where the shielding pattern includes a first portion overlapping the first data line in a plan view, a second portion overlapping the second data line in the plan view, and a first connection portion connecting the first portion and the second portion to each other.

In an embodiment, the first portion, the second portion, and the first connection portion may be integrally connected to each other.

In an embodiment, the first pixel electrode and the second pixel electrode may be disposed between the first data line and the second data line in the plan view.

In an embodiment, the first data line and the second data line may be symmetrically disposed around a virtual line passing between the first sub-pixel circuit and the second sub-pixel circuit and parallel to a second direction crossing the first direction.

In an embodiment, the first portion of the shielding pattern may include an extension portion overlapping the third data line, which is adjacent to the first data line.

In an embodiment, the first conductive layer may further include an auxiliary voltage line extending in a second direction crossing the first direction, and the third data line and the auxiliary voltage line may be symmetrically disposed around a virtual line passing through the third sub-pixel circuit and parallel to the second direction.

In an embodiment, the shielding pattern may be connected to the auxiliary voltage line through a contact hole passing through the second insulating layer.

In an embodiment, the first conductive layer may further include a first driving voltage line disposed between the first data line and the second data line, and a second driving voltage line disposed between the auxiliary voltage line and the third data line.

In an embodiment, the first pixel electrode and the second pixel electrode may overlap the first driving voltage line, and the third pixel electrode may overlap the second driving voltage line in the plan view.

In an embodiment, the shielding pattern may be provided in plurality, the plurality of shielding patterns may be apart from each other in the first direction, and a voltage transferred to a first shielding pattern among the plurality of shielding patterns may be different from a voltage transferred to a second shielding pattern among the plurality of shielding patterns.

In an embodiment, voltages transferred to the plurality of shielding patterns, respectively, may have preset sequences of values that are repeated in the first direction.

In an embodiment, the shielding pattern may be provided in plurality, and the second conductive layer may further include second connection portions connecting the plurality of shielding patterns to each other.

In an embodiment, the plurality of shielding patterns and the second connection portions may be integrally connected to each other.

In an embodiment, the second conductive layer may include a plurality of mesh electrodes apart from each other in the first direction, and each of the plurality of mesh electrodes may include at least two shielding patterns among the plurality of shielding patterns, and the second connection portions connecting the at least two shielding patterns.

In an embodiment, voltages transferred to the plurality of mesh electrodes, respectively, may have preset sequences of values that are repeated in the first direction.

According to one or more embodiments, an electronic apparatus includes a display panel, and a lower cover forming an exterior and defining, in a front surface thereof, an opening exposing a portion of the display panel, where the display panel includes a substrate including a display area and a peripheral area outside the display area, a pixel circuit disposed in the display area and including a first sub-pixel circuit, a second sub-pixel circuit, and a third sub-pixel circuit adjacent to each other in a first direction, a first insulating layer disposed on the pixel circuit, a first conductive layer disposed on the first insulating layer and including a first data line connected to the first sub-pixel circuit, a second data line connected to the second sub-pixel circuit, and a third data line connected to the third sub-pixel circuit, a second insulating layer disposed on the first conductive layer, and a second conductive layer disposed on the second insulating layer and including a first pixel electrode connected to the first sub-pixel circuit, a second pixel electrode connected to the second sub-pixel circuit, a third pixel electrode connected to the third sub-pixel circuit, and a shielding pattern, where the shielding pattern includes a first portion overlapping the first data line in a plan view, a second portion overlapping the second data line in the plan view, and a first connection portion connecting the first portion and the second portion to each other.

In an embodiment, the first portion, the second portion, and the first connection portion of the shielding pattern may be integrally connected to each other.

In an embodiment, the first data line and the second data line may be symmetrically disposed around a virtual line passing between the first sub-pixel circuit and the second sub-pixel circuit and parallel to a second direction crossing the first direction.

In an embodiment, the first portion of the shielding pattern may include an extension portion overlapping the third data line, which is adjacent to the first data line.

In an embodiment, the first conductive layer may further include an auxiliary voltage line extending in a second direction crossing the first direction, and the shielding pattern may be connected to the auxiliary voltage line through a contact hole passing through the second insulating layer.

In an embodiment, the first conductive layer may further include a first driving voltage line disposed between the first data line and the second data line, and a second driving voltage line disposed between the second data line and the third data line, and the shielding pattern may be connected to the first driving voltage line or the second driving voltage line through a contact hole passing through the second insulating layer.

In an embodiment, the shielding pattern may be provided in plurality, the plurality of shielding patterns may be apart from each other in the first direction, and a voltage transferred to a first shielding pattern among the plurality of shielding patterns may be different from a voltage transferred to a second shielding pattern among the plurality of shielding patterns.

In an embodiment, the shielding pattern may be provided in plurality, and the second conductive layer may further include second connection portions connecting the plurality of shielding patterns.

In an embodiment, the plurality of shielding patterns and the second connection portions may be integrally connected.

In an embodiment, the second conductive layer may include a plurality of mesh electrodes apart from each other in the first direction, and each of the plurality of mesh electrodes may include at least two shielding patterns among the plurality of shielding patterns, and the second connection portions connecting the at least two shielding patterns.

In an embodiment, voltages transferred to the plurality of mesh electrodes, respectively, may have preset sequences of values that are repeated in the first direction.

These and/or other aspects will become apparent and more readily appreciated from the following detailed description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view of an electronic apparatus according to an embodiment;

FIG. 2 is an exploded perspective view of an electronic apparatus according to an embodiment;

FIG. 3 is a block diagram of an electronic apparatus according to an embodiment.

FIG. 4 is a schematic plan view of a display panel according to an embodiment;

FIGS. 5A to 5C are equivalent circuit diagrams of a light-emitting diode and a sub-pixel circuit of a display panel according to an embodiment;

FIG. 6 is a schematic plan view of a common voltage supply line and an auxiliary common voltage line of a display panel according to an embodiment;

FIG. 7 is a schematic plan view of voltage lines having a mesh structure according to an embodiment;

FIG. 8 is a schematic view of configuration of voltage lines according to an embodiment;

FIG. 9A is an excerpted plan view of a first conductive layer of a display panel according to an embodiment, FIG. 9B is an excerpted plan view of a second conductive layer of a display panel according to an embodiment, and FIG. 9C is a plan view of a first conductive layer and a second conductive layer overlapping each other, of a display panel according to an embodiment;

FIG. 10 is a schematic plan view of data lines and a shielding pattern, according to an embodiment;

FIG. 11 is a schematic cross-sectional view of the display panel of FIG. 9C, taken along line II-II′ of FIG. 9C;

FIG. 12 is a schematic cross-sectional view of the display panel of FIG. 9C, taken along line III-III′ of FIG. 9C;

FIG. 13 is a schematic cross-sectional view of a display panel according to an embodiment;

FIG. 14 is a schematic plan view of a display panel according to an embodiment;

FIG. 15 is a schematic plan view of a mesh electrode according to an embodiment;

FIG. 16 is a schematic plan view of a display panel according to an embodiment;

FIG. 17 is a schematic plan view of shielding patterns apart from each other, according to an embodiment; and

FIG. 18 is a schematic plan view of pattern groups apart from each other, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various components, such components must not be limited to the above terms. The above terms are used to distinguish one component from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

It will be further understood that, when a layer, region, or component is referred to as being “on” another layer, region, or component, it can be directly or indirectly on the other layer, region, or component. That is, for example, intervening layers, regions, or components may be present.

It will be understood that when a layer, region, or component is referred to as being “connected” to another layer, region, or component, it may be “directly connected” to the other layer, region, or component or may be “indirectly connected” to the other layer, region, or component with other layer, region, or component interposed therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

In the present specification, “A and/or B” means A or B, or A and B. In the present specification, “at least one of A and B”means A or B, or A and B.

In the present specification, an x direction, a y direction and a z direction are not limited to three axes of the rectangular coordinate system, and may be interpreted in a broader sense. For example, the x direction, the y direction, and the z direction may be perpendicular to one another, or may represent different orientations that are not perpendicular to one another.

In this specification, a term “planar” or “plan view” means when a target portion is viewed from above (e.g., when viewed in a direction (z direction) perpendicular to the upper surface of the substrate 100), and a term “cross-sectional” means when a target portion is viewed from the side in a cross-section cut vertically.

In the present specification, when a first element overlaps a second element, it means that the first element is located over or below the second element and at least portions thereof overlap each other in a plan view.

In the case where a certain embodiment may be implemented differently, a specific process order may be performed in the order different from the described order. As an example, two processes successively described may be simultaneously performed substantially and performed in the opposite order.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

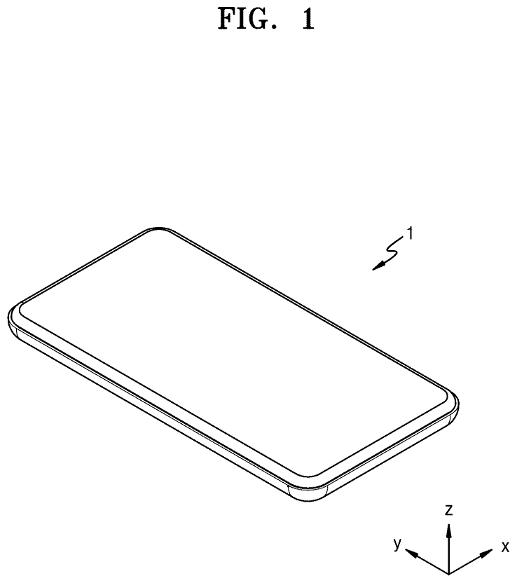

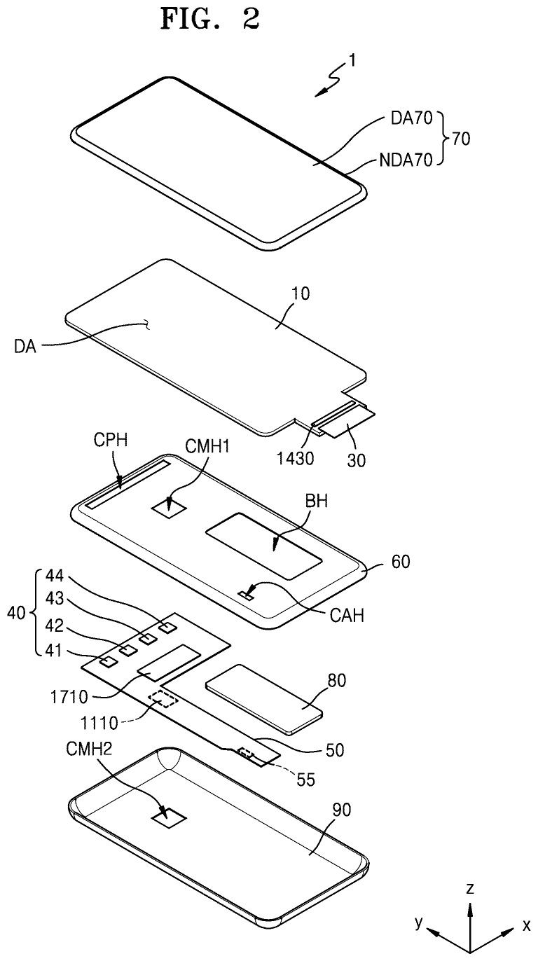

FIG. 1 is a perspective view of an electronic apparatus 1according to an embodiment, and FIG. 2 is an exploded perspective view of the electronic apparatus 1according to an embodiment.

Referring to FIGS. 1 and 2, the electronic apparatus 1 may include an apparatus for displaying moving images or still images and may be used as a display screen of various products including televisions, notebook computers, monitors, advertisement boards, Internet of things (IoTs) apparatuses as well as portable electronic apparatuses including mobile phones, smart phones, tablet personal computers (PCs), mobile communication terminals, electronic organizers, electronic books, portable multimedia players (PMPs), navigations, and ultra mobile personal computers (UMPCs). The electronic apparatus 1 according to an embodiment may be used in wearable devices including smartwatches, watchphones, glasses-type displays, and head-mounted displays (HMDs). The electronic apparatus 1 according to an embodiment may be used as a display in instrument panels for automobiles, center fascias for automobiles, or center information displays (CIDs) arranged on a dashboard, room mirror displays that replace side mirrors of automobiles, and displays of an entertainment system arranged on the backside of front seats for backseat passengers in automobiles.

For convenience of description, it is shown in FIGS. 1 and 2 that the electronic apparatus 1 according to an embodiment is used as a smartphone. The electronic apparatus 1 according to an embodiment may include a cover window 70, a display panel 10, a data driver 1430, a display circuit board 30, a component 40, a bracket 60, a main circuit board 50, a battery 80, and a lower cover 90.

In a plan view of the present specification, “left”, “right”, “up”, and “down” denote directions when the display panel 10 is viewed in a direction perpendicular to the display panel 10. As an example, “left” denotes a −x direction, “right” denotes a +x direction, “up” denotes a +y direction, and “down” denotes a −y direction.

The electronic apparatus 1 may have a rectangular shape in a plan view. As an example, as shown in FIG. 1, the electronic apparatus 1 may have a quadrangular shape having short sides in the x direction and long sides in the y direction in a plan view. A corner where the short side in the x direction meets the long side in the y direction may be round to have a preset curvature or formed to have a right angle. A planar shape of the electronic apparatus 1 is not limited to a rectangle, but may be other polygons, ellipses, or irregular shapes.

The cover window 70 may be disposed on the display panel 10 to cover the upper surface of the display panel 10. Accordingly, the cover window 70 may protect the upper surface of the display panel 10.

The cover window 70 may include a transmissive cover portion DA70 and a light-blocking cover portion NDA70, where the transmissive cover portion DA70 corresponds to the display panel 10, and the light-blocking cover portion NDA70 surrounds the light-blocking cover portion NDA70. The light-blocking cover portion NDA70 may include an opaque material (e.g., a colored opaque material) that blocks light. The light-blocking cover portion NDA70 may include a pattern that may be viewed to a user while images are not displayed.

The display panel 10 may be disposed under the cover window 70. The display panel 10 may overlap the transmissive cover portion DA70 of the cover window 70 in a plan view.

The display panel 10 may include the display area DA. The display area DA is a region in which images are displayed, and may include a region (referred to as a component area, hereinafter) that transmits light emitted from the components 40 disposed below the display panel 10. The component may include external modules such as sensors, cameras, and the like that use visible light, infrared light, sound, and the like.

The display panel 10 may be a light-emitting display panel including a light-emitting diode. The light-emitting diode may include an organic light-emitting diode including an organic emission layer. In an embodiment, the light-emitting diode may be an inorganic light-emitting diode including an inorganic material. The inorganic light-emitting diode may include a PN diode including inorganic material semiconductor-based materials. When a forward voltage is applied to a PN-junction diode, holes and electrons are injected and energy created by recombination of the holes and the electrons is converted to light energy, and thus, light of a preset color may be emitted. The inorganic light-emitting diode may have a width in the range of several micrometers to hundreds of micrometers. In an embodiment, the inorganic light-emitting diode may be denoted by a micro light-emitting diode.

The display panel 10 may be a rigid display panel that has rigidity and thus is not easily bent, or a flexible display panel that is flexible and thus is easily bendable, foldable, or rollable. As an example, the display panel 10 may include a foldable display panel that is foldable and unfoldable, a curved display panel that has a curved display surface, a bended display panel in which a region except a display surface is bent, a rollable display panel that is rollable and unrollable, and a stretchable display panel that is stretchable.

The display panel 10 may be implemented transparent and be a transparent display panel such that an object or background disposed below the display panel 10 is viewable from the upper surface of the display panel 10. Alternatively, the display panel 10 may be a reflective display panel that may reflect an object or background over the upper surface of the display panel 10.

The data driver 1430 may be disposed in the form of an integrated circuit (IC) on the display panel 10. In another embodiment, the data driver 1430 may be disposed on the display circuit board 30.

The display circuit board 30 may be attached on one side of the display panel 10. The display circuit board 30 may be a flexible printed circuit board (FPCB) that may be bent, a rigid printed circuit board (PCB) that is strong and not easily bent, or a composite printed circuit board including both a rigid printed circuit board and a flexible printed circuit board.

In an embodiment, a touch sensor driver may be disposed on the display circuit board 30. The touch sensor driver may include an integrated circuit. The touch sensor driver may be attached to the display circuit board 30. The touch sensor driver may be electrically connected to touch electrodes of a touchscreen layer of the display panel 10 through the display circuit board 30.

The touchscreen layer of the display panel 10 may sense a user's touch input by using at least one of various touch methods such as a resistance layer method, a capacitance method and the like. As an example, in the case where the touchscreen layer of the display panel 10 senses a user's touch input by using a capacitance method, the touch sensor driver may determine whether a user touches the touchscreen layer by applying driving signals to driving electrodes among touch electrodes, and sensing voltages charged in a mutual capacitance between the driving electrodes and the sensing electrodes through the sensing electrodes among the touch electrodes. A user's touch may include a contact touch and a proximity touch. A contact touch denotes that an object such as a user's finger or a pen is in direct contact with the cover window 70 disposed on the touchscreen layer. A proximity touch, like hovering, denotes that an object such as a user's finger or a pen is located near over the cover window 70, away from the cover window 70. The touch sensor driver may be configured to transfer sensor data to a main processor according to sensed voltages, and the main processor may calculate a touch coordinate at which a touch input occurs by analyzing the sensor data.

An auxiliary processor may be disposed on the display circuit board 30, where the auxiliary processor is configured to supply driving voltages for driving pixels of the display panel 10, a scan driver, and the data driver 1430.

A bracket 60 for supporting the display panel 10 may be disposed under the display panel 10. The bracket 60 may include plastic, metal, or both plastic and metal. A first camera hole CMH1 in which a camera module 1710 is inserted, a battery hole BH in which the battery 80 is disposed, and a cable hole CAH through which a cable connected to the display circuit board 30 passes, may be defined in the bracket 60. A component hole CPH overlapping the display panel 10 may be provided in the bracket 60. The component hole CPH may overlap the components 40 of the main circuit board 50 in a third direction (z direction). In an embodiment, the display area DA of the display panel 10 may overlap the components 40 of the main circuit board 50 in the third direction (z direction). In another embodiment, the component hole CPH may not be defined in the bracket 60.

In an embodiment, the components 40 may include first to fourth components 41, 42, 43, and 44 each overlapping the display panel 10 in a plan view. The first to fourth components 41, 42, 43, and 44 may include a proximity sensor, an illuminance sensor, an iris sensor, a face recognition sensor, and a camera (or an image sensor). A proximity sensor that uses an infrared ray may detect an object arranged close to the upper surface of the electronic apparatus 1, and an illuminance sensor may detect brightness of light incident to the upper surface of the electronic apparatus 1. In addition, an iris sensor may capture a person's iris disposed over the upper surface of the electronic apparatus 1, and a camera may capture an object disposed on an upper surface of the electronic apparatus 1. The components 40 are not limited to the proximity sensor, the illuminance sensor, the iris sensor, the face recognition sensor, and the camera. Various modules described below may be disposed.

The main circuit board 50 and the battery 80 may be disposed under the bracket 60. The main circuit board 50 may be a printed circuit board or a flexible printed circuit board.

The main circuit board 50 may include a main processor 1110, a camera module 1710, a main connector 55, and the components 40. The main processor 1110 may include an integrated circuit. The camera module 1710 may be disposed on both the upper surface and the lower surface of the main circuit board 50, and the main processor 1110 and the main connector 55 may each be disposed on one of the upper surface and the lower surface of the main circuit board 50.

The camera module 1710 processes image frames such as still images or moving images obtained by an image sensor in a camera mode, and outputs the image frames to the main processor 1110. The camera module 1710 may include at least one of a camera sensor (e.g., a charge-coupled device (CCD), a complementary metal oxide semiconductor (CMOS), and the like), a photo sensor (or an image sensor), and a laser sensor. The camera module 1710 may be connected to an image sensor among the components 40 overlapping display area DA and may process images input to the image sensor.

The cable 35 passing through the cable hole CAH of the bracket 60 may be connected to the main connector 55, and thus, the main circuit board 50 may be electrically connected to the display circuit board 30.

The lower cover 90 may form an exterior of the electronic apparatus 1, and may define an opening exposing a portion of the display panel 10 in a front surface thereof. The lower cover 90 has an open shape corresponding to the display panel 10 and may be assembled to the display panel 10. The lower cover 90 may be located on the opposite side (i.e., rear side) of the cover window 70 with the display panel 10 therebetween. The lower cover 90 may be disposed under the main circuit board 50 and the battery 80. The lower cover 90 may be fastened and fixed to the bracket 60. The lower cover 90 may form the lower exterior of the electronic apparatus 1. The lower cover 90 may include plastic, metal, or both plastic and metal.

A second camera hole CMH2 through which the lower surface of the camera module 1710 is exposed may be defined in the lower cover 90. The position of the camera module 1710 and the first and second camera holes CMH1 and CMH2 corresponding to the camera module 1710 are not limited to the embodiment shown in FIGS. 1 and 2, but may be variously modified.

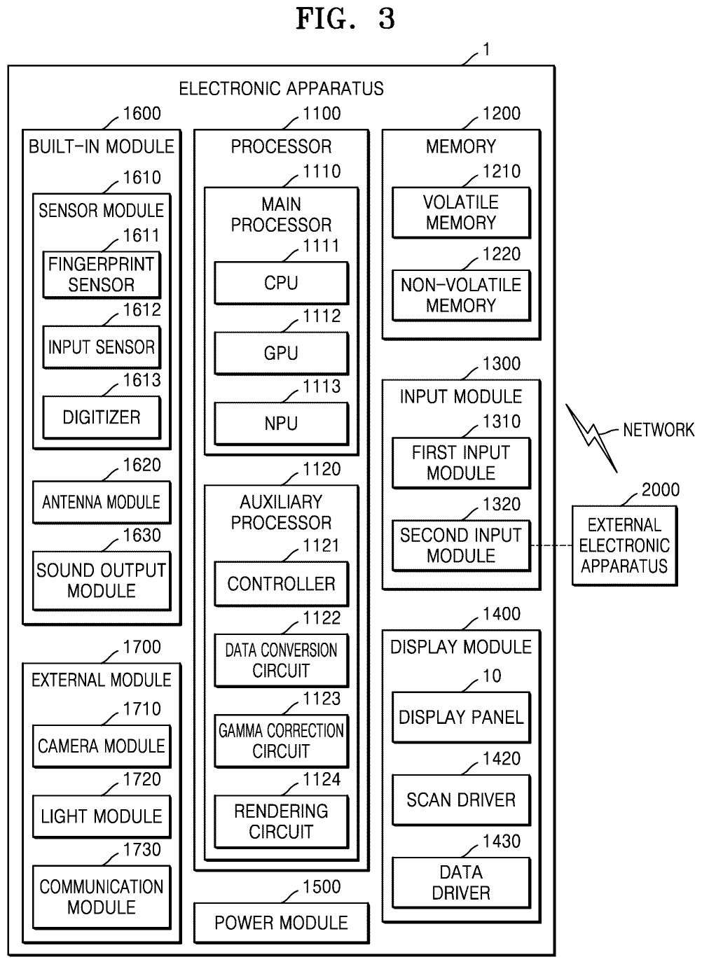

FIG. 3 is a block diagram of the electronic apparatus 1 according to an embodiment.

Referring to FIG. 3, the electronic apparatus 1 may include a processor 1100, a memory 1200, an input module 1300, a display module 1400, a power module 1500, a built-in module 1600, and an external module 1700. According to an embodiment, in the electronic apparatus 1, at least one of the elements may be omitted, or one or more other elements may be added. According to an embodiment, some (e.g., the built-in module 1600) of the elements may be integrated into another element (e.g., the display module 1400).

The processor 1100 may control at least one other element (e.g., a hardware or software element) of the electronic apparatus 1 connected to the processor 1100 by executing software, and perform various data processes or operations. According to an embodiment, as at least some of data processes or operations, the processor 1100 may store commands or data received from another element (e.g., the input module 1300, a sensor module 1610, or a communication module 1730) in a volatile memory 1210, process the commands or data stored in the volatile memory 1210, and store result data in a non-volatile memory 1220.

The processor 1100 may include the main processor 1110 and an auxiliary processor 1120. The main processor 1110 may include at least one of a central processing unit (CPU) 1111 and an application processor (AP). The main processor 1110 may further include at least one of a graphic processing unit (GPU) 1112, a communication processor (CP), and an image signal processor (ISP). The main processor 1110 may further include a neural processing unit (NPU) 1113. The NPU is a processor specialized in processing artificial intelligence models, and the artificial intelligence models may be created through machine learning. The artificial intelligence models may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, and a combination of two or more of the above, but is not limited to the examples described above. The artificial intelligence models may additionally or alternatively include a software structure in addition to a hardware structure. At least two of the processing units and the processors may be implemented as one integrated construction (e.g., a single chip) or respectively implemented as independent constructions (e.g., a plurality of chips).

The auxiliary processor 1120 may include a controller 1121. The controller 1121 may include an interface conversion circuit and a timing control circuit. The controller 1121 receives image signals from the main processor 1110, converts a data format of image signals to match interface specifications of the display module 1400, and outputs image data. The controller 1121 may output various kinds of control signals for driving the display module 1400.

The auxiliary processor 1120 may further include a data processing circuit such as a data conversion circuit 1122, a gamma correction circuit 1123, and a rendering circuit 1124. The data conversion circuit 1122 may receive image data from the controller 1121, correct image data such that images are displayed at desired brightness according to characteristics of the electronic apparatus 1, a user's settings, or the like, or convert image data to reduce power consumption or compensate for an afterimage. The gamma correction circuit 1123 may convert image data, a gamma reference voltage, or the like such that images displayed by the electronic apparatus 1 have desired gamma characteristics. The rendering circuit 1124 may receive image data from the controller 1121, and render the image data by taking into account the pixel configuration of the display panel 10 applied to the electronic apparatus 1. At least one of the data conversion circuit 1122, the gamma correction circuit 1123, and the rendering circuit 1124 may be integrated into another element (e.g., the main processor 1110 or the controller 1121). In an embodiment, the auxiliary processor 1120 may be integrated into the data driver 1430.

The memory 1200 may store various data and input data or output data for commands related thereto, where the various data are used by at least one element (e.g., the processor 1100 or the sensor module 1610) of the electronic apparatus 1. The memory 1200 may include at least one of the volatile memory 1210 and the non-volatile memory 1220.

The input module 1300 may receive commands or data from the outside (e.g., a user or an external electronic apparatus 2000) of the electronic apparatus 1, where the commands or data are to be used by the element (e.g., the processor 1100, the sensor module 1610, or a sound output module 1630) of the electronic apparatus 1.

The input module 1300 may include a first input module 1310 to which commands or data from a user are input, and a second input module 1320 to which commands or data from the external electronic apparatus 2000 are input.

The first input module 1310 may include a microphone, a mouse, a keyboard, or a pen (e.g., a passive pen or active pen). The first input module 1310 may include a mechanical input means such as buttons, a dome switch, a jog wheel, a jog switch, and the like, or a touch input means located on the lower surface or the lateral surface of the electronic apparatus 1. The touch input means may include the touchscreen layer of the display panel 10.

The second input module 1320 may be connected to various kinds of external electronic apparatuses 2000 connected to the electronic apparatus 1 via wires or wirelessly. In an embodiment, the second input module 1320 may include a high definition multimedia interface (HDMI), a universal serial bus (USB) interface, a secure digital (SD) card interface, or an audio interface. The second input module 1320 may include a connector that may physically connect the electronic apparatus 1 to the external electronic apparatus 2000, where the connector includes an HDMI connector, a USB connector, an SD card connector, or an audio connector (e.g., a headphone connector). The electronic apparatus 1 may perform appropriate control related to the connected external electronic apparatus 2000 in response to the external electronic apparatus 2000 being connected to the second input module 1320.

The display module 1400 provides a user with visual information. The display module 1400 may include the display panel 10, a scan driver 1420, and the data driver 1430.

The display panel 10 displays (outputs) information processed by the electronic apparatus 1. The display panel 10 may display execution screen information of an application driven in the electronic apparatus 1, or user interface (UI) and graphic user interface (GUI) information corresponding to the execution screen information.

The scan driver 1420 may be mounted on the display panel 10 as a driving chip. Alternatively, the scan driver 1420 may be directly disposed on the display panel 10. As an example, the scan driver 1420 may include an amorphous silicon thin-film transistor (TFT) gate driver circuit (ASG), a low temperature polycrystalline silicon (LTPS) TFT gate driver circuit, or an oxide semiconductor TFT gate (OSG) driver circuit embedded in the display panel 10. The scan driver 1420 receives control signals from the controller 1121 and outputs scan signals to the display panel 10 in response to control signals.

The display panel 10 may further include an emission control driver. The emission control driver outputs an emission control signal to the display panel 10 in response to a control signal received from the controller 1121. The emission control driver may be formed separately from the scan driver 1420 or integrated in the scan driver 1420.

The data driver 1430 receives a control signal from the controller 1121, converts image data into a data voltage in the form of an analog voltage in response to a control signal, and outputs data voltages to the display panel 10.

The data driver 1430 may be integrated into some elements of the auxiliary processor 1120. As an example, the data driver 1430 may be provided in a timing controller embedded driver IC including the controller 1121.

The power module 1500 supplies power to the elements of the electronic apparatus 1. The power module 1500 may include the battery 800 charging a power voltage. In addition, the power module 1500 has a connection port, and the connection port may be included in the second input module 1320 to which an external charger that supplies power to charge the battery 80 is connected. Alternatively, the power module 1500 may include a wireless power transmission/reception member to charge the battery 80 wirelessly. The wireless power transmission/reception member may include a plurality of coil-shaped antenna radiators. The power module 1500 may include a power management integrated circuit (PMIC). The PMIC supplies power optimized for each of the elements of the electronic apparatus 1.

The electronic apparatus 1 may further include the built-in module 1600 and the external module 1700. The built-in module 1600 may include the sensor module 1610, an antenna module 1620, and the sound output module 1630. The external module 1700 may include the camera module 1710, a light module1720, and the communication module 1730.

The sensor module 1610 may include touch electrodes of the touchscreen layer of the display panel 10, and the touch sensor driver. The sensor module 1610 may sense an input due to a user's body or an input due to a pen, and generate an electrical signal or a data value corresponding to the input. The sensor module 1610 may include at least one of a fingerprint sensor 1611, an input sensor 1612, and a digitizer 1613.

The fingerprint sensor 1611 may generate a data value corresponding to a user's fingerprint. The fingerprint sensor 1611 may include one of an optical fingerprint sensor and a capacitive fingerprint sensor.

The input sensor 1612 may generate a data value corresponding to coordinate information of an input due to a user's body or an input due to a pen. The input sensor 1612 generates an amount of change in a capacitance due to an input as a data value. The input sensor 1612 may sense an input due to a passive pen or transmit/receive data to/from an active pen.

The input sensor 1612 may also measure biological signals such as blood pressure, moisture, or body fat. As an example, in the case where a user touches a portion of the user's body to a sensor layer or sensing panel and does not move for a preset time, the input sensor 1612 may sense bio signals based on a change in the electric field caused by the portion of the user's body, and output information desired by the user to the display module 1400.

The digitizer 1613 may generate a data value corresponding to coordinate information of an input due to a pen. The digitizer 1613 generates a change in electromagnetism due to an input as a data value. The digitizer 1613 may sense an input due to a passive pen or transmit/receive data to/from an active pen.

In an embodiment, at least one of the fingerprint sensor 1611, the input sensor 1612, and the digitizer 1613 may be built into the display panel 10. As an example, at least one of the fingerprint sensor 1611, the input sensor 1612, and the digitizer 1613 may be formed during a process that is successive to the process of forming the pixel circuits and the light-emitting diodes of the display panel 10. Accordingly, the display panel 10 may serve as one of the input modules 1300 that provide an input interface between the electronic apparatus 1 and a user, and also, serve as the display module 1400 that provides an output interface between the electronic apparatus 1 and a user.

In another embodiment, at least two of the fingerprint sensor 1611, the input sensor 1612, and the digitizer 1613 may be formed to be integrated in one sensing panel through the same process. Although the sensing panel may be disposed between the display panel 10 and the cover window 70 disposed on the display panel 10, the disclosure is not limited thereto.

The antenna module 1620 may include at least one antenna for transmitting signals or power to the outside or receiving signals or power from the outside. In an embodiment, the communication module 1730 may transmit signals to an external electronic apparatus or receive signals from an external electronic apparatus through an antenna suitable for a communication method. An antenna pattern of the antenna module 1620 may be integrated in one element (e.g., the display panel 10) of the display module 1400 or the input sensor 1612.

The sound output module 1630 is a device for outputting sound signals to the outside of the electronic apparatus 1, and may output sound data received from the communication module 1730 or stored in the memory 1200 during call signal reception, a communication mode or recording mode, a voice recognition mode, a broadcasting reception mode, and the like. The sound output module 1630 may output sound signals related to a function (e.g., a call signal reception tone, a message reception tone, and the like) performed by the electronic apparatus 1. The sound output module 1630 may include a receiver and a speaker. At least one of the receiver and the speaker may be a sound generator that is attached under the display panel 10 and vibrates the display panel 10 to output sounds. The sound generator may be a piezoelectric element or a piezoelectric actuator that contacts and expands according to electrical signals, or an exciter that generates magnetic force by using a voice coil to vibrate the display panel 10.

The camera module 1710 may capture still images and moving images. In an embodiment, the camera module 1710 may include at least one lens, an image sensor, or an image signal processor. The camera module 1710 may further include an infrared camera that may measure whether a user is present, a user's position, a user's gaze, and the like.

The light module 1720 may output signals for informing occurrence of an event using light of a light source, or provide light to obtain images. Here, examples of event occurrence include message reception, call signal reception, a missed call, an alarm, a calendar reminder, receiving an email, being notified of battery charge information, and the like. The light module 1720 may include a light-emitting diode or a xenon lamp. The light module 1720 may emit light of a single color or multiple colors to the front or back of the electronic apparatus 1. The light module 1720 may operate in cooperation with the camera module 1710 or independently.

The communication module 1730 may establish a wired or wireless communication channel between the electronic apparatus 1 and the external electronic apparatus 2000, and perform communication through the established communication channel. The communication module 1730 may include one or both of a wireless communication module, such as a cellular communication module, a short-range wireless communication module, or a global navigation satellite system (GNSS) communication module, and a wired communication module, such as a local area network (LAN) communication module, or a power line communication module. The communication module 1730 may transmit and receive wireless signals on the Internet using at least one of a wireless LAN) (WLAN), wireless-fidelity (Wi-Fi), Wi-Fi direct, and digital living network alliance (DLNA) technologies. In addition, the communication module 1730 may support short-range communication using at least one of Bluetooth™, RFID radio frequency identification (RFID), infrared data association (IrDA), ultra-wideband (UWB), ZigBee, near field communication (NFC), Wi-Fi, Wi-Fi Direct, and wireless USB technologies. The above-described various kinds of communication modules 1730 may be implemented in one chip or respectively implemented as separate chips.

In addition, the electronic apparatus 1 may further include the components 40 generating electrical signals or data values corresponding to an inner state or external state of the electronic apparatus 1. The components 40 may include, for example, a proximity sensor, an illumination sensor, an acceleration sensor, a magnetic sensor, a G-sensor, a gyroscope sensor, a motion sensor, an RGB sensor, an infrared sensor, a finger scan sensor, an ultrasonic sensor, an optical sensor, an environment sensor (e.g., a barometer, a hygrometer, a thermometer, a radiation detection sensor, a heat detection sensor, a gas detection sensor, and the like), a chemical sensor (e.g., an electronic nose, a healthcare sensor, a biometric sensor, and the like).

The electronic apparatus 1 outputs various information through the display module 1400 within an operating system. When the processor 1100 executes an application stored in the memory 1200, the display module 1400 provides a user with application information through the display panel 10.

The processor 1100 outputs commands or data to the display module 1400, the sound output module 1630, the camera module 1710, or the light module 1720 based on input data received from the input module 1300 or the sensor module 1610. As an example, the processor 1100 may generate image data corresponding to input data and output the same to the display module 1400, or generate command data corresponding to input data and output the same to the camera module 1710 or the light module 1720. When input data is not received from the input module 1300 for a preset time, the processor 1100 switches an operation mode of the electronic apparatus 1 into a low-power mode or a sleep mode to reduce power consumed by the electronic apparatus 1.

The processor 1100 obtains an external input through the input module 1300 or the sensor module 1610, and executes an application corresponding to the externa input. As an example, in the case where a user selects a camera icon displayed on the display panel 10, the processor 1100 obtains a user input through the input sensor 1612 and activates the camera module 1710. The processor 1100 transfers image data corresponding to a captured image obtained through the camera module 1710 to the display module 1400. The display module 1400 may display an image corresponding to the captured image through the display panel 10.

As another example, in the case where the display module 1400 executes personal information authentication, the fingerprint sensor 1611 obtains input fingerprint information as input data. The processor 1100 compares the input data obtained through the fingerprint sensor 1611 with authentication data stored in the memory 1200, and executes an application according to a comparison result. The display module 1400 may display information executed according to a logic of an application through the display panel 10.

As another example, in the case where a music streaming icon displayed on the display module 1400 is selected, the processor 1100 obtains a user input through the input sensor 1612, and activates a music streaming application stored in the memory 1200. When a music execution command is input in the music streaming application, the processor 1100 activates the sound output module 1630 and provides a user with sound information matching the music execution command.

Some of the elements may be connected to each other through a communication method between peripheral devices, such as a bus, general purpose input/output (GPIO), serial peripheral interface (SPI), mobile industry processor interface (MIPI), or ultra path interconnect (UPI) link, to exchange signals (e.g., commands or data) with each other. In an embodiment, the main processor 1110 may transfer image signals to the auxiliary processor 1120 through the MIPI.

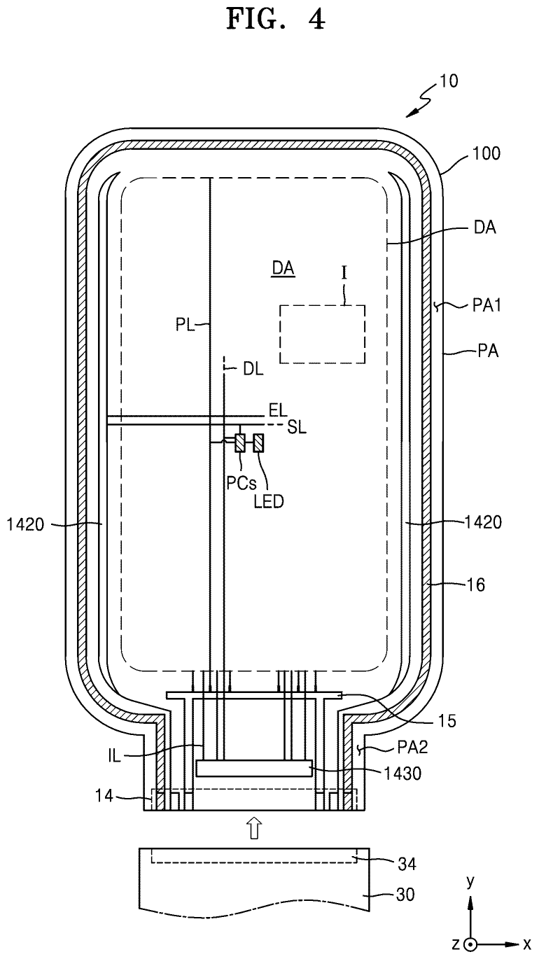

FIG. 4 is a schematic plan view of the display panel 10 according to an embodiment.

Referring to FIG. 4, the display panel 10 may include a display area DA and a peripheral area PA outside the display area DA. The display area DA is a region in which images are displayed and a plurality of pixels may be disposed. The display area DA may have various shapes, for example, circular shapes, elliptical shapes, polygonal shapes, or shapes of specific figures. As an example, it is shown in FIG. 4 that the display area DA has an approximately rectangular shape having round corners.

The peripheral area PA may be disposed outside the display area DA. The peripheral area PA may include a first peripheral area PA1 and a second peripheral area PA2, where the first peripheral area PA1 is disposed to surround at least a portion of the display area DA, and the second peripheral area PA2 is adjacent to one side of the display area DA and extends in a second direction (e.g., a y direction). The width of the second peripheral area PA2 in a first direction (e.g., an x direction) may be less than the width of the display area DA. At least a portion of the second peripheral area PA2 may be easy to bend through this structure. In an embodiment, the display panel 10 may be bent around a bending axis crossing the second peripheral area PA2.

A planar shape of the display panel 10 shown in FIG. 4 may be substantially equal to the shape of the substrate 100 included in the display panel 10. When the display panel 10 includes the display area DA and the peripheral area PA outside the display area DA, it may represent the substrate 100 includes the display area DA and the peripheral area PA outside the display area DA. Hereinafter, for convenience, description is made on the assumption that the substrate 100 includes the display area DA and the peripheral area PA.

The substrate 100 may include glass, metal, or polymer resin. The substrate 100 may include polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers including the above-described polymer resin, and an inorganic material layer disposed therebetween.

The pixels may be disposed in the display area DA, and the display area DA may display images using light emitted from the pixels. Each pixel may include a plurality of sub-pixels. As an example, one pixel may include a red sub-pixel, a green sub-pixel, and a blue sub-pixel. Each sub-pixel may include a light-emitting diode LED, and the light-emitting diode LED may be electrically connected to a sub-pixel circuit PCs. The sub-pixel circuit PCs and the light-emitting diode LED may be disposed in the display area DA.

The scan driver 1420, the data driver 1430, a pad portion 14, a driving voltage supply line 15, and a common voltage supply line 16 may be disposed in the peripheral area PA.

The scan driver 1420 may be configured to provide scan signals to the sub-pixel circuit PCs through a scan line SL. The scan line SL may be a gate line connected to a gate of switching transistors included in the sub-pixel circuit PCs. Scan signals may be gate signals that turn on or turn off the switching transistors included in the sub-pixel circuit PCs. The scan drivers 1420 may be disposed on two opposite sides of the peripheral area PA with the display area DA therebetween. Some of the sub-pixel circuits PCs disposed in the display area DA may be electrically connected to the scan driver 1420 disposed in the left (−x direction), and the rest may be electrically connected to the scan driver 1420 disposed in the right (+x direction). In another embodiment, the scan driver 1420 may be disposed in only one side of the peripheral area PA.

The pad portion 14 may be disposed in the second peripheral area PA2 of the substrate 100. The pad portion 14 may include a plurality of pads electrically connected to the display circuit board 30 exposed by not being covered by an insulating layer. A pad 34 of the display circuit board 30 may be electrically connected to the pad portion 14 of the display panel 10.

The display circuit board 30 transfers signals of the auxiliary processor 1120 to the display panel 10. Control signals generated by the auxiliary processor 1120 may be transferred to the scan driver 1420 and the data driver 1430 through the display circuit board 30. In an embodiment, the display circuit board 30 may include a power management IC (not shown). The power management IC may provide a driving voltage ELVDD and a common voltage ELVSS to the driving voltage supply line 15 and the common voltage supply line 16, respectively. The driving voltage ELVDD may be provided to the sub-pixel circuit PCs through a driving voltage line PL connected to the driving voltage supply line 15, and the common voltage ELVSS may be provided to an opposite electrode of the light-emitting diode LED connected to the common voltage supply line 16. The driving voltage supply line 15 may extend in the first direction (e.g., x direction). The common voltage supply line 16 may have a loop shape having one open side and partially surround the display area DA.

Data signals may be transferred to the sub-pixel circuit PCs through the data line DL electrically connected to an input line IL through the input line IL.

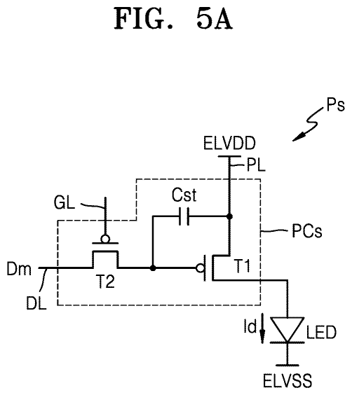

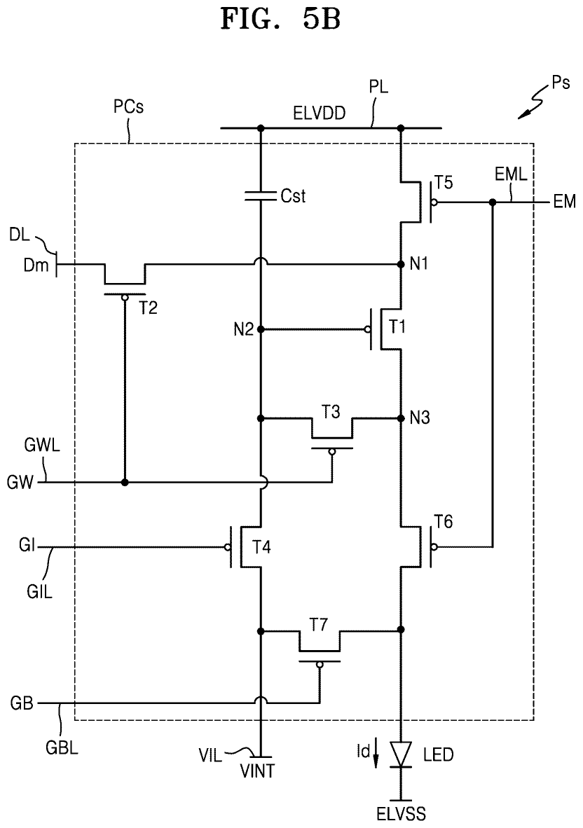

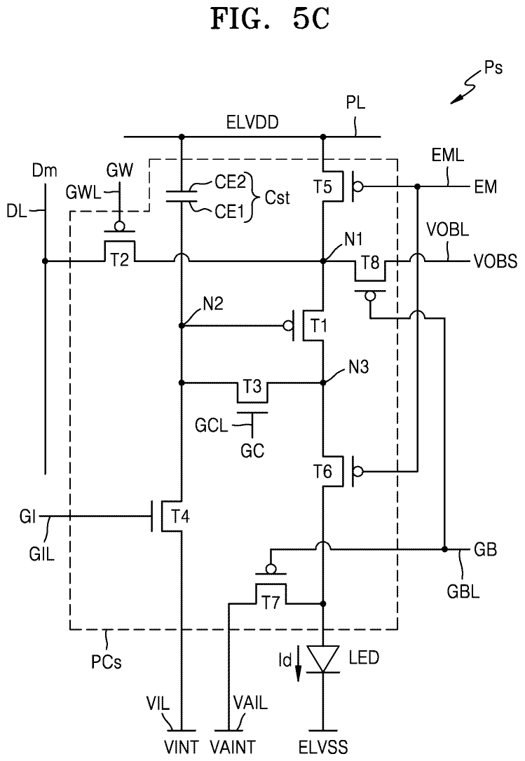

FIGS. 5A to 5C are equivalent circuit diagrams of the light-emitting diode LED and the sub-pixel circuit PCs of the display panel 10 according to an embodiment.

Referring to FIG. 5A, the sub-pixel circuit PCs may be connected to the light-emitting element LED to implement light emission of sub-pixels. The light-emitting diode LED may emit red, green, blue, or white light. The sub-pixel circuit PCs may include a first transistor T1, which is a driving transistor, a second transistor T2, which is a switching transistor, and a capacitor Cst. The second transistor T2 may be connected to a gate line GL and the data line DL, and configured to transfer a data signal Dm to the first transistor T1 according to a gate signal, where the data signal Dm is input through the data line DL, and the gate signal is input through the gate line GL.

The capacitor Cst may be connected to a gate of the first transistor T1 and the driving voltage line PL and configured to store a voltage corresponding to a difference between a voltage transferred from the second transistor T2 and the driving voltage ELVDD supplied to the driving voltage line PL.

The first transistor T1 may be connected to the driving voltage line PL and the capacitor Cst and configured to control a driving current I_{d} according to the voltage stored in the capacitor Cst, the driving current I_{d} flowing from the driving voltage line PL to the light-emitting diode LED. The light-emitting diode LED may be configured to emit light at a preset brightness based on the driving current I_{d}.

Referring to FIG. 5B, the sub-pixel circuit PCs may include first to seventh transistors T1, T2, T3, T4, T5, T6, and T7, and a storage capacitor Cst. Depending on the type (p-type or n-type) and/or an operation condition of a transistor, a first terminal of each of the first to seventh transistors T1, T2, T3, T4, T5, T6, and T7 may be a source or a drain, and a second terminal may be a terminal different from the first terminal. As an example, in the case where the first terminal is a source, the second terminal may be a drain. The first transistor T1 may be the driving transistor in which the magnitude of a source-drain current thereof is determined according to a gate-source voltage Vgs thereof, and the second to seventh transistors T2, T3, T4, T5, T6, and T7 may be switching transistors that are turned on/off according to a gate-source voltage or a gate voltage.

The sub-pixel circuit PCs may be connected to a first gate line GWL, a second gate line GIL, a third gate line GBL, an emission control line EL, the data line DL, the driving voltage line PL, and a first initialization voltage line VIL, where the first gate line GWL is configured to transfer first scan signals GW, the second gate line GIL is configured to transfer second scan signals GI, the third gate line GBL is configured to transfer third scan signals GB, the emission control line EL is configured to transfer emission control signals EM, the data line DL is configured to transfer data signals Dm, the driving voltage line PL is configured to transfer the driving voltage ELVDD, and the first initialization voltage line VIL is configured to transfer a first initialization voltage VINT.

The first transistor T1 may include a gate, a first terminal, and a second terminal, where the gate is connected to a second node N2, the first terminal is connected to a first node N1, and the second terminal is connected to a third node N3. The first transistor T1 receives a data signal Dm according to a switching operation of the second transistor T2 and is configured to supply the driving current I_{d} to the light-emitting diode OLED. The light-emitting diode LED may be an organic light-emitting diode.

The second transistor T2 may include a gate, a first terminal, and a second terminal, where the gate is connected to the first gate line GWL, the first terminal is connected to the data line DL, and the second terminal is connected to the first node N1. The second transistor T2 may be turned on according to a first gate signal GW transferred through the first gate line GWL and may perform a switching operation of transferring a data signal Dm to the first node N1, where the data signal Dm is transferred through the data line DL.

The third transistor T3 may include a gate, a first terminal, and a second terminal, where the gate is connected to the first gate line GWL, the first terminal is connected to the second node N2, and the second terminal is connected to the third node N3. The third transistor T3 may be turned on according to a first gate signal GW to diode-connect the first transistor T1, where the first gate signal GW is transferred through the first gate line GWL.

The fourth transistor T4 may include a gate, a first terminal, and a second terminal, where the gate is connected to the second gate line GIL, the first terminal is connected to the first initialization voltage line VIL, and the second terminal is connected to the second node N2. The fourth transistor T4 may be turned on according to a second gate signal GI to initialize the gate voltage of the first transistor T1 by transferring the first initialization voltage VINT to the gate of the first transistor T1, where the second gate signal GI is transferred through the second gate line GIL.

The fifth transistor T5 may include a gate, a first terminal, and a second terminal, where the gate is connected to the emission control line EML, the first terminal is connected to the driving voltage line PL, and the second terminal is connected to the first node N1. The sixth transistor T6 may include a gate, a first terminal, and a second terminal, where the gate is connected to the emission control line EML, the first terminal is connected to the third node N3, and the second terminal is connected to a pixel electrode of the light-emitting diode LED. The fifth transistor T5 and the sixth transistor T6 are simultaneously turned on according to an emission control signal EM, and the driving current I_{d} flows through the light-emitting element LED, where the emission control signal EM is transferred through the emission control line EML.

The seventh transistor T7 may include a gate, a first terminal, and a second terminal, where the gate is connected to the third gate line GBL, the first terminal is connected to the second terminal of the sixth transistor T6 and the pixel electrode of the light-emitting diode LED, and the second terminal is connected to the first initialization voltage line VIL. The seventh transistor T7 may be turned on according to a third gate signal GB to initialize the pixel electrode of the light-emitting element LED by transferring the first initialization voltage VINT to the pixel electrode of the light-emitting element LED, where the third gate signal GB is transferred through the third gate line GBL. The seventh transistor T7 may be omitted.

The storage capacitor Cst may include a first capacitor electrode and a second capacitor electrode, where the first capacitor electrode is connected to the second node N2, and the second capacitor electrode is connected to the driving voltage line PL.

The light-emitting diode LED may include the pixel electrode (e.g., an anode) and a common electrode (e.g., a cathode) facing the pixel electrode, where the common electrode may be configured to receive the common voltage ELVSS. The light-emitting element LED may display images by receiving the driving current I_{d} from the first transistor T1 and emitting light of a preset color.

Referring to FIG. 2C, the sub-pixel circuit PCs may include first to eighth transistors T1, T2, T3, T4, T5, T6, T8, and T8, and the storage capacitor Cst. The first transistor T1 may be the driving transistor in which the magnitude of a source-drain current thereof is determined according to a gate-source voltage Vgs thereof, and the second to eighth transistors T2, T3, T4, T5, T6, T7, and T8 may be switching transistors that transfer signals.

The sub-pixel circuit PCs may be connected to a first gate line GWL, a second gate line GIL, a third gate line GBL, a fourth gate line GCL, an emission control line EML, the data line DL, the driving voltage line PL, a first initialization voltage line VIL, a second initialization voltage line VAIL, and a bias voltage line VOBL, where the first gate line GWL is configured to transfer first scan signals GW, the second gate line GIL is configured to transfer second scan signals GI, the third gate line GBL is configured to transfer third scan signals GB, the fourth gate line GCL is configured to transfer fourth gate signals GC, the emission control line EML is configured to transfer emission control signals EM, the data line DL is configured to transfer data signals Dm, the driving voltage line PL is configured to transfer the driving voltage ELVDD, the first initialization voltage line VIL is configured to transfer a first initialization voltage VINT, the second initialization voltage line VAIL is configured to transfer a second initialization voltage line VIL, and the bias voltage line VOBL is configured to transfer a bias voltage VOBS.

The first transistor T1 may include a gate, a first terminal, and a second terminal, where the gate is connected to a second node N2, the first terminal is connected to a first node N1, and the second terminal is connected to a third node N3. The first transistor T1 receives a data signal Dm according to a switching operation of the second transistor T2 and is configured to supply the driving current I_{d} to the light-emitting diode OLED.

The second transistor T2 may include a gate, a first terminal, and a second terminal, where the gate is connected to the first gate line GWL, the first terminal is connected to the data line DL, and the second terminal is connected to the first node N1. The second transistor T2 may be turned on according to a first gate signal GW transferred through the first gate line GWL and may perform a switching operation of transferring a data signal Dm to the first node N1, where the data signal Dm is transferred through the data line DL.

The third transistor T3 may include a gate, a first terminal, and a second terminal, where the gate is connected to the fourth gate line GCL, the first terminal is connected to the second node N2, and the second terminal is connected to the third node N3. The third transistor T3 may be turned on according to a fourth gate signal GC to diode-connect the first transistor T1, where the fourth gate signal GC is transferred through the fourth gate line GCL.

The fourth transistor T4 may include a gate, a first terminal, and a second terminal, where the gate is connected to the second gate line GIL, the first terminal is connected to the first initialization voltage line VIL, and the second terminal is connected to the second node N2. The fourth transistor T4 may be turned on according to a second gate signal GI to initialize the gate voltage of the first transistor T1 by transferring the first initialization voltage VINT to the gate of the first transistor T1, where the second gate signal GI is transferred through the second gate line GIL.

The fifth transistor T5 may include a gate, a first terminal, and a second terminal, where the gate is connected to the emission control line EML, the first terminal is connected to the driving voltage line PL, and the second terminal is connected to the first node N1. The sixth transistor T6 may include a gate, a first terminal, and a second terminal, where the gate is connected to the emission control line EML, the first terminal is connected to the third node N3, and the second terminal is connected to a pixel electrode of the light-emitting diode LED. The fifth transistor T5 and the sixth transistor T6 are simultaneously turned on according to an emission control signal EM, and the driving current I_{d} flows through the light-emitting element LED, where the emission control signal EM is transferred through the emission control line EML.

The seventh transistor T7 may include a gate, a first terminal, and a second terminal, where the gate is connected to the third gate line GBL, the first terminal is connected to the second terminal of the sixth transistor T6 and the pixel electrode of the light-emitting diode LED, and the second terminal is connected to the second initialization voltage line VAIL. The seventh transistor T7 may be turned on according to a third gate signal GB to initialize the pixel electrode of the light-emitting element LED by transferring the second initialization voltage VAINT to the pixel electrode of the light-emitting element LED, where the third gate signal GB is transferred through the third gate line GBL, and the second initialization voltage VAINT is transferred from the second initialization voltage line VAIL.

The eighth transistor T8 includes a gate, a first terminal, and a second terminal, where the gate is connected to the third gate line GBL, the first terminal is connected to the first node N1, and the second terminal is connected to the bias voltage line VOBL. The eighth transistor T8 may be turned on according to a third gate signal GB transferred through the third gate line GBL, and be configured to transfer the bias voltage VOBS to the first node N1, where the bias voltage VOBS is transferred from the bias voltage line VOBL.

The storage capacitor Cst may include a first capacitor electrode and a second capacitor electrode, where the first capacitor electrode is connected to the second node N2, and the second capacitor electrode is connected to the driving voltage line PL.

The light-emitting diode LED may include the pixel electrode (e.g., an anode) and a common electrode (e.g., a cathode) facing the pixel electrode, where the common electrode may be configured to receive the common voltage ELVSS. The light-emitting element LED may display images by receiving the driving current I_{d} from the first transistor T1 and emitting light of a preset color.

Although it is shown in FIGS. 5A and 5B that transistors of the sub-pixel circuit PCs are P-type transistors, the embodiment is not limited thereto. As another example, the transistors of the sub-pixel circuit PCs may be N-type transistors, or as shown in FIG. 5C, some transistors may be P-type transistors and other transistors may be N-type transistors. As an example, the third transistor T3 and the fourth transistor T4 may be N-type transistors, and the rest may be P-type transistors. The sub-pixel circuits PCs of FIGS. 5A to 5C are provided as examples, and the design of the sub-pixel circuits PCs according to the disclosure may be variously modified.

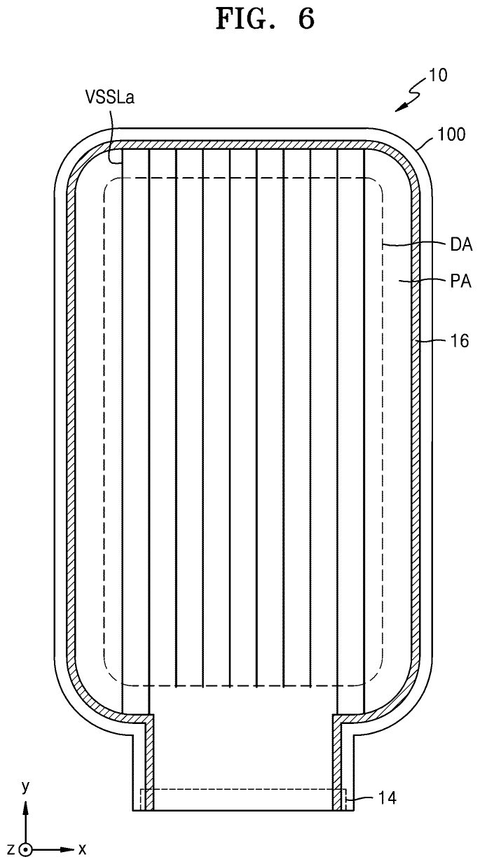

FIG. 6 is a schematic plan view of a common voltage supply line and an auxiliary common voltage line of the display panel 10 according to an embodiment.

Referring to FIG. 6, the display panel 10 may include the display area DA and the peripheral area PA outside the display area DA. The pad portion 14 may be disposed on one side of a substrate 100. The pad portion 14 may be electrically connected to the display circuit board 30.

The common voltage supply line 16 may be disposed in the peripheral area PA. The common voltage supply line 16 may have a loop shape having one open side and partially surround the display area DA. The common voltage supply line 16 may be electrically connected to the power management integrated circuit of the display circuit board 30 through the pad portion 14 to receive the common voltage ELVSS.

In an embodiment, the display panel 10 may include auxiliary common voltage lines VSSLa disposed in the display area DA. The auxiliary common voltage lines VSSLa may each extend in the second direction (e.g., y direction) and be disposed apart from each other in the first direction (e.g., x direction). The auxiliary common voltage lines VSSLa may each be electrically connected to the common voltage supply line 16 on the upper side (+y direction) and/or the lower side (−y direction) of the peripheral area PA to receive the common voltage ELVSS. In an embodiment, the auxiliary common voltage lines VSSLa may each be electrically connected to the opposite electrode of the light-emitting diode LED through auxiliary electrodes (not shown) in the display area DA. The display panel 10 may reduce a voltage drop of the common voltage ELVSS due to a resistance of the opposite electrode through the auxiliary common voltage lines VSSLa. Accordingly, the display panel 10 may display high-quality images by preventing or reducing brightness deterioration due to the voltage drop of the common voltage ELVSS.

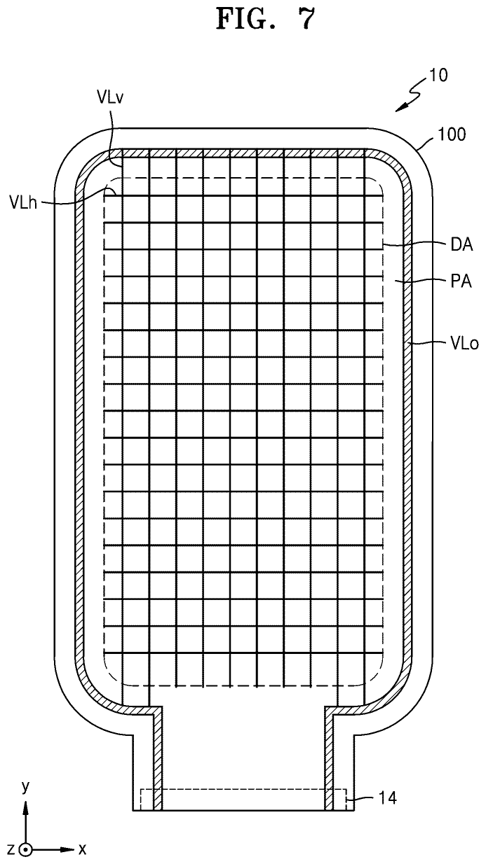

FIG. 7 is a schematic plan view of voltage lines having a mesh structure according to an embodiment.

Referring to FIG. 7, the display panel 10 may include the display area DA and the peripheral area PA outside the display area DA. The pad portion 14 may be disposed on one side of a substrate 100. The pad portion 14 may be electrically connected to the display circuit board 30.

A voltage supply line VLo may be disposed in the peripheral area PA. In an embodiment, the voltage supply line VLo may have a loop shape having one open side and partially surround the display area DA. In another embodiment, the voltage supply lines VLo may be disposed on two opposite sides of the peripheral area PA with the display area DA therebetween. The voltage supply line VLo may be electrically connected to the power management integrated circuit of the display circuit board 30 through the pad portion 14 to receive a direct current (DC) voltage.

The display panel 10 may include horizontal voltage lines VLh and vertical voltage lines VLv disposed in the display area DA. The horizontal voltage lines VLh may each extend in the first direction (e.g., x direction) and be disposed apart from each other in the second direction (e.g., y direction). The horizontal voltage lines VLh may each be electrically connected to the voltage supply line VLo on the left (−x direction) and/or the right (+x direction) of the peripheral area PA to receive a DC voltage. The horizontal voltage lines VLh may each be electrically connected to the sub-pixel circuits PCs disposed in the same row to transfer a DC voltage to the sub-pixel circuits PCs.

The vertical voltage lines VLv may each extend in the second direction (e.g., y direction) and be disposed apart from each other in the first direction (e.g., x direction). The vertical voltage lines VLv may be disposed on a layer different from the horizontal voltage lines VLh. The vertical voltage lines VLv may each be electrically connected to the horizontal voltage lines VLh through contact holes disposed in the display area DA to form a mesh structure. In an embodiment, the vertical voltage lines VLv may each be electrically connected to the voltage supply line VLo on the upper side (+y direction) and/or the lower side (−y direction) of the peripheral area PA.

A DC voltage may be one of the voltages supplied to the sub-pixel circuits PCs. As an example, the DC voltage may be the first initialization voltage VINT, the second initialization voltage VAINT, or the bias voltage VOBS. When the DC voltage is the first initialization voltage VINT, the horizontal voltage line VLh may be the first initialization voltage line VIL, and the vertical voltage line VLv may be a first auxiliary initialization voltage line. When the DC voltage is the second initialization voltage VAINT, the horizontal voltage line VLh may be the second initialization voltage line VAIL, and the vertical voltage line VLv may be a second auxiliary initialization voltage line. When the DC voltage is the bias voltage VOBS, the horizontal voltage line VLh may be the bias voltage line VOBL, and the vertical voltage line VLv may be an auxiliary bias voltage line. The mesh structure may reduce a brightness deviation for each position of each sub-pixel by reducing a DC voltage drop.

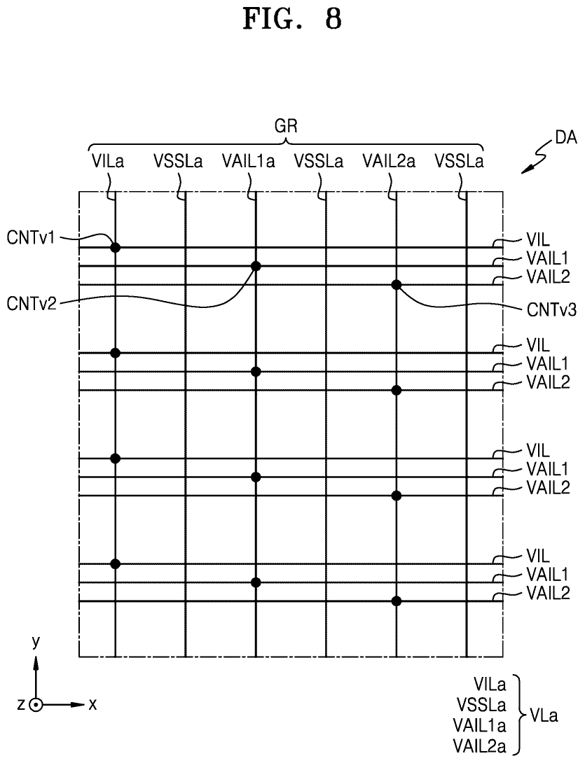

FIG. 8 is a schematic view of configuration of voltage lines according to an embodiment.

Referring to FIG. 8, the first initialization voltage line VIL, a second-1 initialization voltage line VAIL1, and a second-2 initialization voltage line VAIL2 extending in the first direction (e.g., x direction), and the auxiliary voltage lines VLa extending in the second direction (e.g., y direction) may be disposed in the display area DA of the display panel 10.

The first initialization voltage lines VIL may each transfer the first initialization voltage VINT to the sub-pixel circuits PCs disposed in the same row. In an embodiment, the second initialization voltage VAINT transferred to the sub-pixel circuit PCs may be different depending on a color of light emitted by the light-emitting diode LED electrically connected to the sub-pixel circuit PCs. The second-1 initialization voltage line VAIL1 and the second-2 initialization voltage line VAIL2 may each correspond to the second initialization voltage line VAIL described with reference to FIG. 5C. As an example, the second-1 initialization voltage lines VAIL1 may each be electrically connected to red sub-pixel circuits PCs among the sub-pixel circuits PCs disposed in the same row to transfer a second-1 initialization voltage. The second-2 initialization voltage lines VAIL2 may each be electrically connected to blue sub-pixel circuits PCs and green sub-pixel circuits PCs among the sub-pixel circuits PCs disposed in the same row to transfer a second-2 initialization voltage.

The auxiliary voltage lines VLa may be disposed apart from each other in the first direction (e.g., x direction), and voltages transferred by the auxiliary voltage lines VLa, respectively, may have preset sequences of values that are repeated in the first direction (e.g., x direction). In an embodiment, a first auxiliary voltage line VLa may be a first auxiliary initialization voltage line VILa transferring the first initialization voltage VINT. A third auxiliary voltage line VLa may be a second-1 auxiliary initialization voltage line VAIL1a transferring a second-1 initialization voltage. A fifth auxiliary voltage line VLa may be a second-2 auxiliary initialization voltage line VAIL2a transferring a second-2 initialization voltage. Each of a second auxiliary voltage line VLa, a fourth auxiliary voltage line VLa, and a sixth auxiliary voltage line VLa may be the auxiliary common voltage line VSSLa transferring the common voltage ELVSS. The six auxiliary voltage lines VLa disposed in the order in the first direction (e.g., x direction) may be defined as one auxiliary voltage line group GR. Auxiliary voltage line groups GR may be repeatedly disposed in the first direction (e.g., x direction) in the display area DA.

The first auxiliary initialization voltage lines VILa may be electrically connected to the first initialization voltage lines VIL in the display area DA through first contact holes CNTv1. The first initialization voltage lines VIL and the first auxiliary initialization voltage lines VILa may form a mesh structure transferring the first initialization voltage VINT.

The second-1 initialization voltage lines VAIL1 may be electrically connected to the second-1 auxiliary initialization voltage lines VAIL1a in the display area DA through second contact holes CNTb1. The second-1 initialization voltage lines VAIL1 and the second-1 auxiliary initialization voltage lines VAIL1a may form a mesh structure transferring the second-1 initialization voltage.

The second-2 initialization voltage lines VAIL2 may be electrically connected to the second-2 auxiliary initialization voltage lines VAIL2a in the display area DA through third contact holes CNTb3. The second-2 initialization voltage lines VAIL2 and the second-2 auxiliary initialization voltage lines VAIL2a may form a mesh structure transferring the second-2 initialization voltage.

The auxiliary common voltage lines VSSLa may not be electrically connected to other voltage lines disposed below the auxiliary common voltage lines VSSLa in the display area DA. The auxiliary common voltage lines VSSLa may be electrically connected to the common voltage supply line 16 in the peripheral area PA to transfer the common voltage ELVSS.

Although it is shown in FIG. 8 that the auxiliary voltage line group GR includes six auxiliary voltage lines VLa, the disclosure is not limited thereto. In another embodiment, the auxiliary voltage line group GR may include fewer or more auxiliary voltage lines VLa. As an example, the auxiliary voltage line group GR may further include an auxiliary bias voltage line, and the auxiliary bias voltage lines may be electrically connected to the bias voltage lines VOBL in the display area DA to form a mesh structure transferring the bias voltage VOBS. The design of the order of voltages transferred by the auxiliary voltage lines VLa included in the auxiliary voltage line group GR may be variously changed.

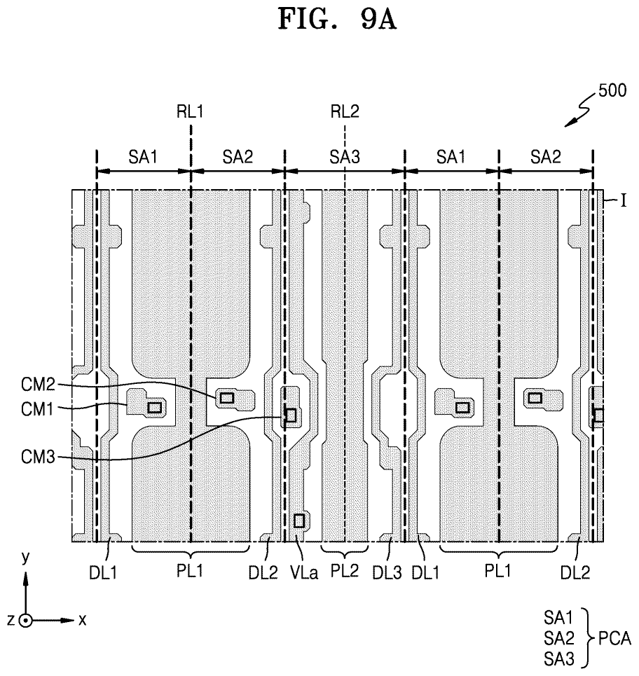

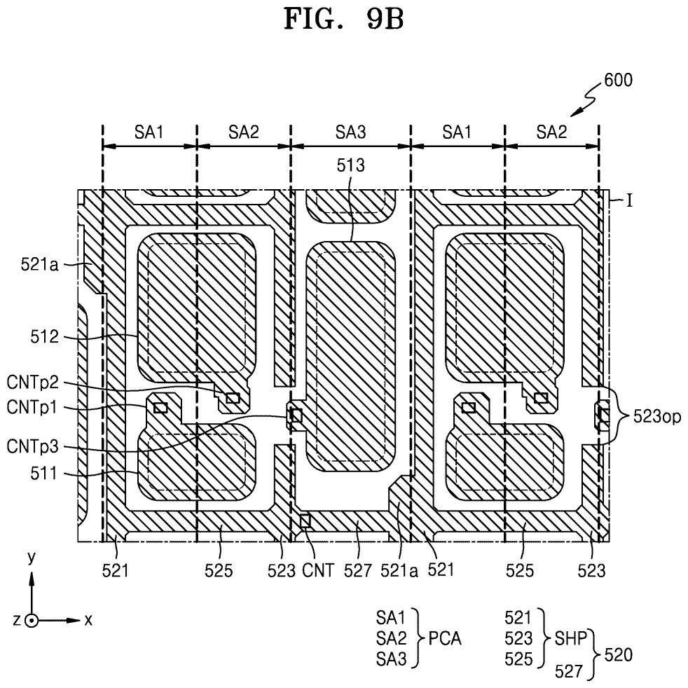

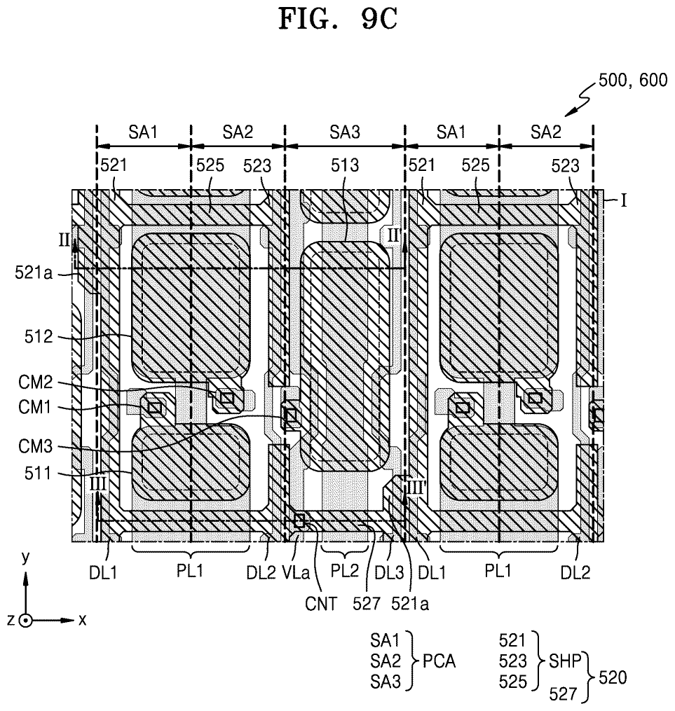

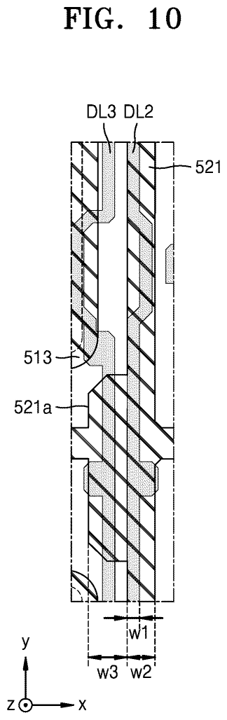

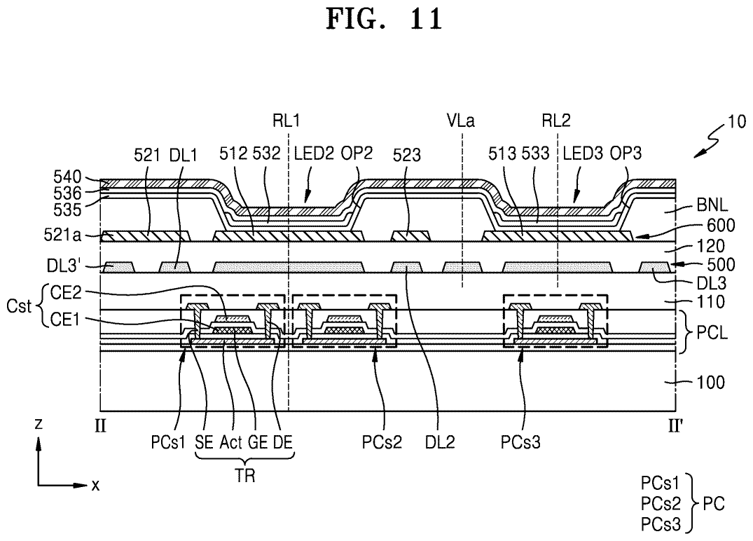

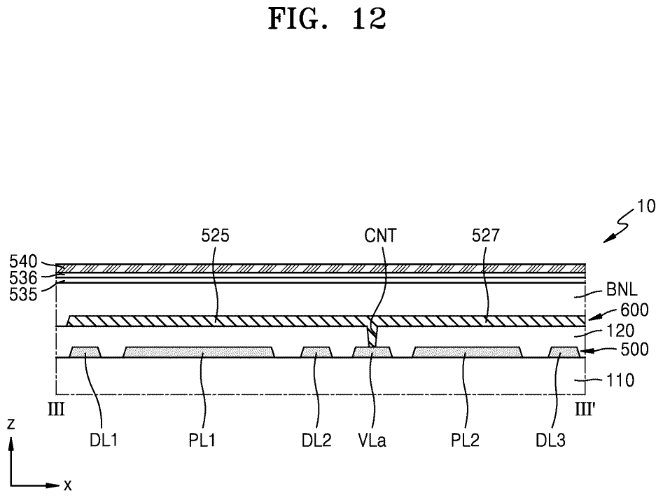

FIG. 9A is an excerpted plan view of a first conductive layer of the display panel 10 according to an embodiment, FIG. 9B is an excerpted plan view of a second conductive layer of the display panel 10 according to an embodiment, and FIG. 9C is a plan view of the first conductive layer and the second conductive layer of the display panel 10 overlapping each other according to an embodiment. FIG. 10 is a schematic plan view of data lines and a shielding pattern according to an embodiment. FIG. 11 is a schematic cross-sectional view of the display panel 10 of FIG. 9C, taken along line II-II′ of FIG. 9C, and FIG. 12 is a schematic cross-sectional view of the display panel 10 of FIG. 9C, taken along line III-III′ of FIG. 9C.

Referring to FIGS. 9A to 9C, and 11, the display panel 10 may include the substrate 100, the pixel circuit PC disposed on the substrate 100, and light-emitting diodes LED2 and LED3 disposed on the pixel circuit PC.

A pixel circuit layer PCL including the pixel circuit PC may be disposed on the substrate 100. The pixel circuit PC may be disposed in a pixel circuit area PCA, and may include a first sub-pixel circuit PCs1, a second sub-pixel circuit PCs2, and a third sub-pixel circuit PCs3. The first sub-pixel circuit PCs1, the second sub-pixel circuit PCs2, and the third sub-pixel circuit PCs3 may be disposed adjacent to each other in the first direction (e.g., x direction). The first sub-pixel circuit PCs1 may be disposed in a first sub-area SA1, the second sub-pixel circuit PCs2 may be disposed in a second sub-area SA2, and the third sub-pixel circuit PCs3 may be disposed in a third sub-area SA3.

Each of the first sub-pixel circuit PCs1, the second sub-pixel circuit PCs2, and the third sub-pixel circuit PCs3 may include at least one transistor TR and the storage capacitor Cst. The transistor TR may include a semiconductor layer Act, a gate electrode GE, a source electrode SE, and a drain electrode DE, where the gate electrode GE overlaps a channel region of the semiconductor layer Act in a plan view, the source electrode SE is electrically connected to a source region of the semiconductor layer Act, and the drain electrode DE is electrically connected to a drain region of the semiconductor layer Act. In an embodiment, at least one switching transistor (not shown) may be disposed between the channel region and the source region SE or drain region DE of the transistor TR.

In an embodiment, the semiconductor layer Act may include a silicon-based semiconductor material or an oxide-based semiconductor material. The silicon-based semiconductor material may include low temperature polysilicon (LTPS) including amorphous silicon, polycrystalline silicon, and the like. The oxide-based semiconductor material may include at least one selected from among indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). As an example, the oxide-based semiconductor material may include an InSnZnO (ITZO), an InGaZnO (IGZO), or the like.

The storage capacitor Cst may include a first capacitor electrode CE1 and a second capacitor electrode CE2 overlapping the first capacitor electrode CE1 in a plan view. In an embodiment, the first capacitor electrode CE1 may be integrally connected to the gate electrode GE of the transistor TR.

At least one insulating layer may be disposed between the semiconductor layer Act and the gate electrode GE of the transistor TR, between the first capacitor electrode CE1 and the second capacitor electrode CE2, and between the second capacitor electrode CE2 and the source electrode SE and the drain electrode DE.

A first insulating layer 110 may be disposed on the pixel circuit layer PCL. The first insulating layer 110 may include an organic insulating material such as acryl, benzocyclobutene (BCB), polyimide, or hexamethyldisiloxane (HMDSO).

A first conductive layer 500 may be disposed on the first insulating layer 110. The first conductive layer 500 may include aluminum (Al), platinum (Pt), palladium (Pd), silver (Ag), magnesium (Mg), gold (Au), nickel (Ni), neodymium (Nd), iridium (Ir), chrome (Cr), lithium (Li), calcium (Ca), molybdenum (Mo), titanium (Ti), tungsten (W), and/or copper (Cu), and include a single layer or a multi-layer including the above materials. In an embodiment, the first conductive layer 500 may have a three-layered structure of a titanium layer/an aluminum layer/a titanium layer.

The first conductive layer 500 may include a first data line DL1, a second data line DL2, a third data line DL3, a first driving voltage line PL1, a second driving voltage line PL2, and the auxiliary voltage line VLa. The first conductive layer 500 may include a first connection electrode CM1, a second connection electrode CM2, and a third connection electrode CM3. The first data line DL1, the second data line DL2, the third data line DL3, the first driving voltage line PL1, the second driving voltage line PL2, and the auxiliary voltage line VLa may extend approximately in the second direction (e.g., y direction). Here, that the wiring extends approximately in the second direction (e.g., y direction) means that some portion of the wiring may be bent and extend in the first direction (e.g., the x direction), and the like.

The first data line DL1, the second data line DL2, and the third data line DL3 may be connected to the first sub-pixel circuit PCs1, the second sub-pixel circuit PCs2, and the third sub-pixel circuit PCs3, respectively, to transfer data signals Dm. The first data line DL1 may be disposed on the left (−x direction) of the first sub-area SA1, and the second data line DL2 may be disposed on the right (+x direction) of the second sub-area SA2. In an embodiment, the first data line DL1 and the second data line DL2 may be disposed symmetrically around a virtual line RL1 passing between the first sub-pixel circuit PCs1 and the second sub-pixel circuit PCs2 and parallel to the second direction (e.g., y-direction).

The first driving voltage line PL1 and the second driving voltage line PL2 may transfer the driving voltage ELVDD to the first sub-pixel circuit PCs1, the second sub-pixel circuit PCs2, and the third sub-pixel circuit PCs3. The first driving voltage line PL1 may be disposed in the first sub-area SA1 and the second sub-area SA2, and the second driving voltage line PL2 may be disposed in the third sub-area SA3. The first driving voltage line PL1 may be disposed between the first data line DL1 and the second data line DL2 and may overlap the first sub-pixel circuit PCs1 and the second sub-pixel circuit PCs2 in a plan view. The second driving voltage line PL2 may be disposed between the second data line DL2 and the third data line DL3 and may overlap the third sub-pixel circuit PCs3 in a plan view.

The auxiliary voltage line VLa may be a wiring transferring a DC voltage. As an example, the auxiliary voltage line VLa may be the first auxiliary initialization voltage line VILa, the second-1 auxiliary initialization voltage line VAIL1a, the second-2 auxiliary initialization voltage line VAIL2a, or the auxiliary common voltage line VSSLa. In an embodiment, the auxiliary voltage line VLa may be disposed between the second data line DL2 and the second driving voltage line PL2 in a plan view. The third data line DL3 and the auxiliary voltage line VLa may be disposed symmetrically around a virtual line RL2 passing across the third sub-pixel circuit PCs3 and parallel to the second direction (e.g., y-direction).

In each pixel circuit area PCA, the first data line DL1, the first driving voltage line PL1, the second data line DL2, the auxiliary voltage line VLa, the second driving voltage line PL2, and the third data line DL3 may be sequentially disposed in the first direction (e.g., x direction).

The second insulating layer 120 may be disposed on the first conductive layer 500. The second insulating layer 120 may include an organic insulating material such as acryl, benzocyclobutene (BCB), polyimide, or hexamethyldisiloxane (HMDSO).

A second conductive layer 600 may be disposed on the second insulating layer 120. The second conductive layer 600 may include a first pixel electrode 511, a second pixel electrode 512, a third pixel electrode 513, and a mesh electrode 520. The second conductive layer 600 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The second conductive layer 600 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the second conductive layer 600 may further include a layer on/under the reflective layer, the layer including ITO, IZO, ZnO, AZO, or In₂O₃.

The first pixel electrode 511 may be electrically connected to the first sub-pixel circuit PCs1 through the first connection electrode CM1. The second pixel electrode 512 may be electrically connected to the second sub-pixel circuit PCs2 through the second connection electrode CM2. The third pixel electrode 513 may be electrically connected to the third sub-pixel circuit PCs3 through the third connection electrode CM3.

Each of the first pixel electrode 511 and the second pixel electrode 512 may be disposed over the first sub-area SA1 and the second sub-area SA2. The first pixel electrode 511 and the second pixel electrode 512 may be disposed between the first data line DL1 and the second data line DL2 in a plan view. Each of the first data line DL1 and the second data line DL2 may be apart from the first pixel electrode 511 and the second pixel electrode 512 in a plan view. Accordingly, because the first data line DL1, the second data line DL2, the first pixel electrode 511, and the second pixel electrode 512 have a sufficient distance, coupling between the data lines and the pixel electrodes may be reduced.

The first pixel electrode 511 and the second pixel electrode 512 may overlap the first driving voltage line PL1 in a plan view. That is, the first driving voltage line PL1 may be disposed between the first sub-pixel circuit PCs1 and the first pixel electrode 511 and between the second sub-pixel circuit PCs2 and the second pixel electrode 512. Accordingly, the first driving voltage line PL1 may reduce coupling between the first sub-pixel circuit PCs1 and the first pixel electrode 511 and coupling between the second sub-pixel circuit PCs2 and the second pixel electrode 512.

The third pixel electrode 513 may be disposed in the third sub-area SA3. The third pixel electrode 513 may be disposed between the auxiliary voltage line VLa and the third data line DL3 in a plan view. The third pixel electrode 513 may overlap the third data line DL3 and the auxiliary voltage line VLa in a plan view. Because the third data line DL3 and the auxiliary voltage line VLa are disposed symmetrically around the virtual line RL2 passing across the third sub-pixel circuit PCs3, bending of the third pixel electrode 513 due to the lower structure may be symmetrical around the virtual line RL2. Accordingly, a brightness deviation of the third light-emitting diode LED3 due to a user's viewing angles may be reduced.

In addition, the third pixel electrode 513 may overlap the second driving voltage line PL2 in a plan view. The second driving voltage line PL2 may effectively reduce coupling between the third sub-pixel circuit PCs3 and the third pixel electrode 513.

The mesh electrode 520 may include second connection portions 527 connecting a plurality of shielding patterns SHP to a plurality of adjacent shielding patterns SHP. Each of the shielding patterns SHP may include a first portion 521 overlapping the first data line DL1, a second portion 523 overlapping the second data line DL2, and first connection portions 525 connecting the first portion 521 to the second portion 523. The first portion 521 and the second portion 523 may extend approximately in the second direction (e.g., y direction), and the first connection portions 525 may extend in the first direction (e.g., x direction) across the first driving voltage line PL1.

In an embodiment, the shielding pattern SHP may define an opening 523op adjacent to the third pixel electrode 513 to prevent contact with the third pixel electrode 513. The second portion 523 of the shielding pattern SHP may be separated into a plurality of portions due to the opening 523op.

The shielding patterns SHP adjacent in the first direction (e.g., x direction) may be connected to each other by the second connection portions 527. The second connection portion 527 may extend in the first direction (e.g., x direction) across the second driving voltage line PL2. The first portion 521, the second portion 523, the first connection portion 525, and the second connection portion 527 may be integrally connected to each other to form the mesh electrode 520.

Referring to FIG. 10, the first data line DL1 may have a first width w1 in the first direction (e.g., x direction). The first portion 521 of the shielding pattern SHP overlapping the first data line DL1 in a plan view may have a second width w2 in the first direction (e.g., x direction), and the second width w2 may be greater than the first width w1. In an embodiment, the first portion 521 of the shielding pattern SHP may have a sufficient width to cover all of bent portions of the first data line DL1. Likewise, the second data line DL2 may have the first width w1 in the first direction (e.g., x direction), and the second portion 523 of the shielding pattern SHP overlapping the second data line DL2 in a plan view may have the second width w2 greater than the first width w1 in the first direction (e.g., x direction). The first portion 521 of the shielding pattern SHP may be disposed between the first data line DL1 and the opposite electrode 540 in a cross-sectional view, and the second portion 523 may be disposed between the second data line DL2 and the opposite electrode 540 in a cross-sectional view. Accordingly, the shielding pattern SHP may effectively reduce coupling between the first data line DL1, the second data line DL2, and the opposite electrode 540.

The first data line DL1 may be disposed adjacent to the third data line DL3 electrically connected to the third sub-pixel circuit PCs3 disposed in a previous column. The first portion 521 of the shielding pattern SHP may have an extension portion 521a protruding by a third width w3 in a fourth direction (e.g., −x direction). The extension portion 521a may overlap a portion of the third data line DL3 adjacent to the first portion 521 in a plan view. The extension portion 521a of the shielding pattern SHP may be disposed between the third data line DL3 and the opposite electrode 540 in a cross-sectional view.

Because the third data line DL3 is disposed to partially overlap or be very adjacent to the third pixel electrode 513, a pattern shielding the third data line DL3 is difficult to form. Accordingly, coupling between the third data line DL3 and the opposite electrode 540 may be reduced by covering at least a portion of the third data line DL3 using the extension portion 521a protruding from the first portion 521 of the shielding pattern SHP.

A bank layer BNL may be disposed on the second conductive layer 600. The bank layer BNL may cover the outer portions of each of the first pixel electrode 511, the second pixel electrode 512, and the third pixel electrode 513. The inner portions of the first pixel electrode 511, the second pixel electrode 512, and the third pixel electrode 513 may overlap an intermediate layer through a first opening OP1, a second opening OP2, and a third opening OP3 respectively defined in the bank layer BNL in a plan view.

The bank layer BNL may include an organic insulating material such as polyamide, an acryl resin, benzocyclobutene, and hexamethyldisiloxane (HMDSO), and be formed by spin coating and the like.

The intermediate layer may be disposed on the bank layer BNL. The intermediate layer may include a first emission layer overlapping the first pixel electrode 511, a second emission layer 532 overlapping the second pixel electrode 512, and a third emission layer 533 overlapping the third pixel electrode 513 in a plan view. The intermediate layer may include a first functional layer 535 disposed between the pixel electrodes and the emission layers, and/or a second functional layer 536 disposed between the emission layers and the opposite electrode 540. Each of the first functional layer 535 and the second functional layer 536 may include a hole transport layer (HTL), a hole injection layer (HIL), an electron transport layer (ETL), and/or an electron injection layer (EIL). Each of the first functional layer 535 and the second functional layer 536 may extend to overlap the plurality of pixel electrodes in a plan view.

In an embodiment, the intermediate layer may include a first stack including the emission layer and the functional layer, a second stack including the emission layer and the functional layer, and a charge generation layer between the first stack and the second stack. The charge generation layer may include a negative charge generation layer and a positive charge generation layer. A light-emission efficiency of a tandem type light-emitting diode LED including the plurality of emission layers, may be enhanced even more by the negative charge generation layer and the positive charge generation layer.

The negative charge generation layer may be an n-type charge generation layer. The negative charge generation layer may be configured to supply electrons. The negative charge generation layer may include a host and a dopant. The host may include an organic material. The dopant may include a metal material. The positive charge generation layer may be a p-type charge generation layer. The positive charge generation layer may be configured to supply holes. The positive charge generation layer may include a host and a dopant. The host may include an organic material. The dopant may include a metal material.

The opposite electrode 540 may be disposed on the intermediate layer. The opposite electrode 540 may include a conductive material having a relatively low work function. As an example, the opposite electrode 540 may include a (semi) transparent layer including silver (Ag), magnesium (Mg), aluminum (Al), nickel (Ni), chromium (Cr), lithium (Li), calcium (Ca) or an alloy thereof. Alternatively, the opposite electrode 540 may further include a layer on the (semi) transparent layer, the layer including ITO, IZO, ZnO, or In₂O₃. In an embodiment, the opposite electrode 540 may include silver (Ag) and magnesium (Mg). The opposite electrode 540 may be disposed to correspond to the plurality of light-emitting diodes. In other words, the opposite electrode 540 may extend to overlap the plurality of pixel electrodes in a plan view.

A stack structure of the first pixel electrode 511, the intermediate layer, and the opposite electrode 540 may correspond to a first light-emitting diode, a stack structure of the second pixel electrode 512, the intermediate layer, and the opposite electrode 540 may correspond to a second light-emitting diode LED2, and a stack structure of the third pixel electrode 513, the intermediate layer, and the opposite electrode 540 may correspond to a third light-emitting diode LED3.

Referring to FIGS. 9C and 12, the shielding pattern SHP may be electrically connected to the auxiliary voltage line VLa in the lower portion through a contact hole CNT passing through the second insulating layer 120 to receive a DC voltage. In an embodiment, the auxiliary voltage line VLa may be the first auxiliary initialization voltage line VILa, the second-1 auxiliary initialization voltage line VAIL1a, the second-2 initialization voltage line VAIL2, or the auxiliary common voltage line VSSLa.

In an embodiment, in the case where the auxiliary voltage line VLa is the first auxiliary initialization voltage line VILa, the first initialization voltage VINT may be transferred to the shielding pattern SHP. Adjacent shielding patterns SHP may be connected to each other by the second connection portions 527 to form the mesh electrode 520. The display panel 10 may have a double mesh structure of the first initialization voltage line VIL, the first auxiliary initialization voltage line VILa, and the mesh electrode 520. Accordingly, the display panel 10 may prevent or reduce a voltage drop of the first initialization voltage VINT due to a resistance of the first initialization voltage line VIL and the first auxiliary initialization voltage line VILa.

In the case where the auxiliary voltage line VLa is the auxiliary common voltage line VSSLa, the common voltage ELVSS may be transferred to the shielding pattern SHP. Due to a double connection structure of the mesh electrode 520 and the auxiliary common voltage line VSSLa, the display panel 10 may prevent or reduce a voltage drop of the common voltage ELVSS in the first direction (e.g., x direction) in the display area DA.

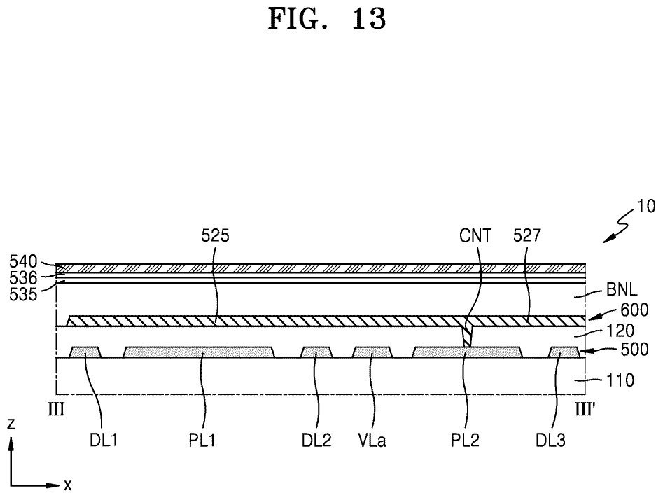

Referring to FIG. 13, the shielding pattern SHP may be electrically connected to the second driving voltage line PL2 through a contact hole CNT passing through the second insulating layer 120. In another embodiment, the shielding pattern SHP may be electrically connected to the first driving voltage line PL1 through a contact hole passing through the second insulating layer 120. The driving voltage ELVDD may be transferred to the shielding pattern SHP.

In another embodiment, the shielding pattern SHP may not be electrically connected to the voltage lines in the lower portion in the display area DA. In the display area DA, the shielding pattern SHP and the voltage lines below the shielding pattern SHP may be electrically separated from each other by the second insulating layer 120. The shielding pattern SHP may extend to the peripheral area PA and be electrically connected to the driving voltage supply line 15, the common voltage supply line 16, or the voltage supply line VLo.

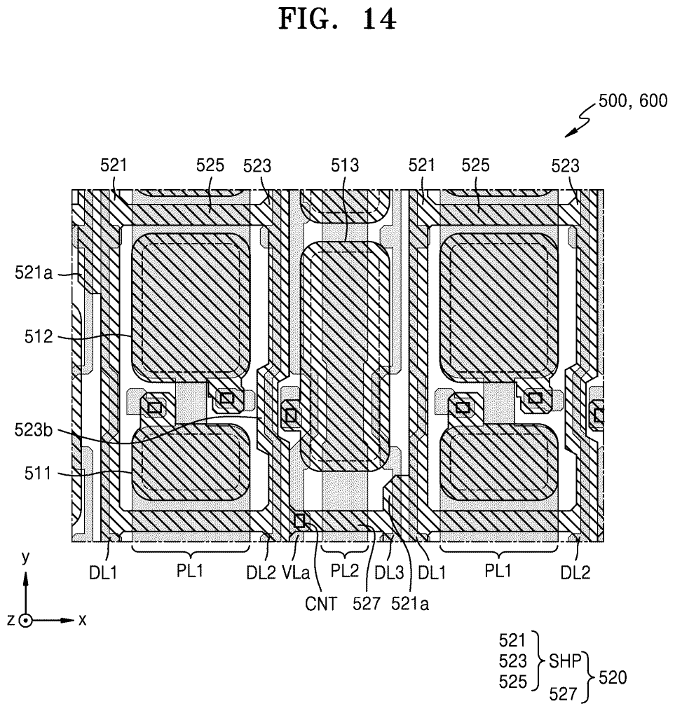

FIG. 14 is a schematic plan view of the display panel 10 according to an embodiment.

Referring to FIG. 14, the mesh electrode 520 may include the second connection portions 527 connecting the shielding patterns SHP to the shielding patterns SHP. Each of the shielding patterns SHP may include the first portion 521 overlapping the first data line DL1, the second portion 523 overlapping the second data line DL2, and the first connection portions 525 connecting the first portion 521 to the second portion 523.

The shielding pattern SHP may include a curved portion 523b that detours the third pixel electrode 513 such that the second portion 523 is sufficiently apart from the third pixel electrode 513. Although it is shown in FIG. 14 that the curved portion 523b completely covers the second data line DL2, the disclosure is not limited thereto. In another embodiment, the curved portion 523b may be partially offset from the second data line DL2 in a plan view to detour the third pixel electrode 513. Because the second portion 523 is connected without being separated by the curved portion 523b, a resistance of the shielding pattern SHP may be reduced.

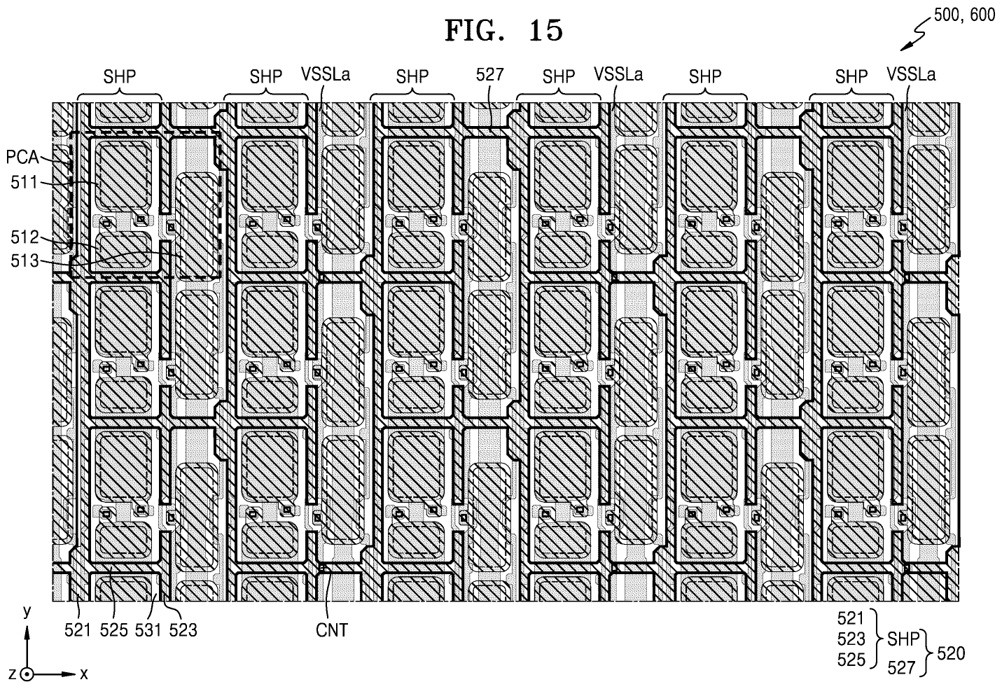

FIG. 15 is a schematic plan view of the mesh electrode 520 according to an embodiment.

Referring to FIG. 15, the display panel 10 may include the first conductive layer 500 and the second conductive layer 600 disposed on the first conductive layer 500. The first conductive layer 500 may include the first data line DL1, the second data line DL2, the third data line DL3, the first driving voltage line PL1, the second driving voltage line PL2, and the auxiliary voltage lines VLa extending in the second direction (e.g., y direction). The second conductive layer 600 may include the first pixel electrode 511, the second pixel electrode 512, the third pixel electrode 513, and the mesh electrode 520.

The mesh electrode 520 may include the second connection portions 527 connecting the shielding patterns SHP to the adjacent shielding patterns SHP. Each of the shielding patterns SHP may include the first portion 521 overlapping the first data line DL1, the second portion 523 overlapping the second data line DL2, and the first connection portion 525 connecting the first portion 521 to the second portion 523. The first portion 521, the second portion 523, the first connection portion 525, and the second connection portion 527 included in one mesh electrode 520 may be integrally connected to each other. In an embodiment, the mesh electrode 520 may be disposed over the entire surface of the display area DA. That is, the shielding patterns SHP and the second connection portions 527 disposed in the display area DA may be all integrally connected.

As described with reference to FIG. 8, a voltage transferred by each of the auxiliary voltage lines VLa may have preset sequences of values that are repeated in the first direction (e.g., x direction). As an example, the auxiliary voltage lines VLa may be repeatedly disposed in the first direction (e.g., x direction) in the order of the first auxiliary initialization voltage line VILa, the auxiliary common voltage line VSSLa, the second-1 auxiliary initialization voltage line VAIL1a, the auxiliary common voltage line VSSLa, the second-2 auxiliary initialization voltage line VAIL2a, and the auxiliary common voltage line VSSLa. The mesh electrode 520 may be electrically connected to the auxiliary voltage lines VLa transferring the same voltage through contact holes CNT. As an example, as shown in FIG. 15, the mesh electrode 520 may be electrically connected to only the auxiliary common voltage lines VSSLa through contact holes CNT. The mesh electrode 520 and other auxiliary voltage lines VLa, for example, the first auxiliary initialization voltage line VILa, the second-1 auxiliary initialization voltage line VAIL1a, and the second-2 auxiliary initialization voltage line VAIL2a may be electrically separated from each other by the second insulating layer 120.

In another embodiment, the mesh electrode 520 may be electrically connected to one kind of voltage lines among the first auxiliary initialization voltage lines VILa, the second-1 auxiliary initialization voltage lines VAIL1a, and the second-2 auxiliary initialization voltage lines VAIL2a through contact holes CNT. In another embodiment, the mesh electrode 520 may be electrically connected to the first driving voltage lines PL1 and/or the second driving voltage lines PL2 through contact holes CNT.

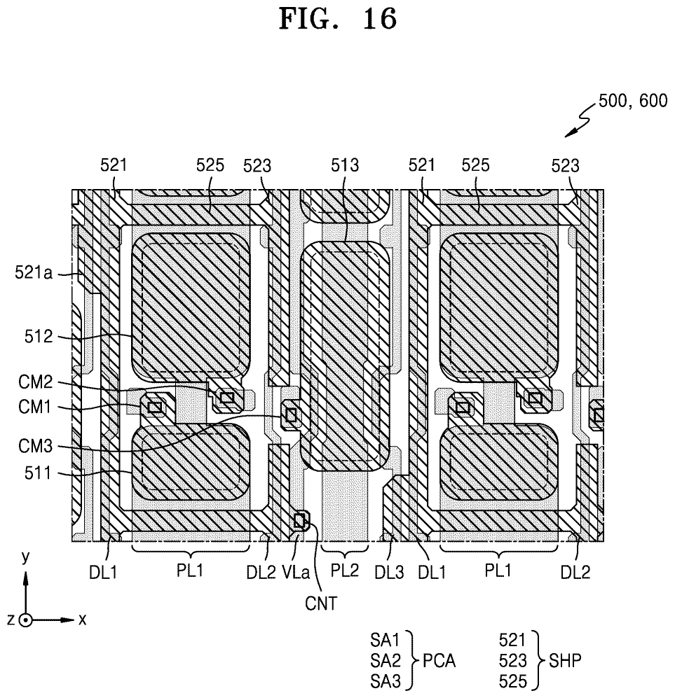

FIG. 16 is a schematic plan view of the display panel 10 according to an embodiment.

Referring to FIG. 16, the display panel 10 may include the first conductive layer 500 and the second conductive layer 600 disposed on the first conductive layer 500. The first conductive layer 500 may include the first data line DL1, the second data line DL2, the third data line DL3, the first driving voltage line PL1, the second driving voltage line PL2, and the auxiliary voltage line VLa extending in the second direction (e.g., y direction). The auxiliary voltage line VLa may include the auxiliary common voltage line VSSLa. The first conductive layer 500 may include the first connection electrode CM1, the second connection electrode CM2, and the third connection electrode CM3. The second conductive layer 600 may include the first pixel electrode 511 electrically connected to the first connection electrode CM1, the second pixel electrode 512 electrically connected to the second connection electrode CM2, the third pixel electrode 513 electrically connected to the third connection electrode CM3, and the shielding patterns SHP.

Each of the shielding patterns SHP may include a first portion 521 overlapping the first data line DL1, a second portion 523 overlapping the second data line DL2, and first connection portions 525 connecting the first portion 521 to the second portion 523. The first portion 521 and the second portion 523 may extend approximately in the second direction (e.g., y direction), and the first connection portions 525 may extend in the first direction (e.g., x direction) across the first driving voltage line PL1.

The first portion 521 of the shielding pattern SHP may have an extension portion 521a protruding by a third width w3 in a fourth direction (e.g.,-x direction). The extension portion 521a may overlap a portion of the third data line DL3 adjacent to the first portion 521 in a plan view. In an embodiment, the shielding pattern SHP may define the opening 523op adjacent to the third pixel electrode 513 not to be in contact with the third pixel electrode 513. The second portion 523 of the shielding pattern SHP may be separated into a plurality of portions due to the opening 523op. In another embodiment, the shielding pattern SHP may include the curved portion 523b that detours the third pixel electrode 513 not to be in contact with the third pixel electrode 513.

In an embodiment, the shielding pattern SHP may be electrically connected to the auxiliary voltage line VLa in the lower portion through a contact hole CNT passing through the second insulating layer 120 to receive a DC voltage. Here, the DC voltage may be one of voltages supplied to the sub-pixel circuits PCs and the light-emitting diodes LED. As an example, the DC voltage may be the first initialization voltage VINT, the second-1 initialization voltage, the second-2 initialization voltage, or the common voltage ELVSS.

In another embodiment, the shielding pattern SHP may be electrically connected to the first driving voltage line PL1 or the second driving voltage line PL2 in the lower portion through a contact hole passing through the second insulating layer 120 to receive the driving voltage ELVDD.

The shielding patterns SHP adjacent to each other may be apart from each other in the first direction (e.g., x direction). In an embodiment, the shielding patterns SHP may be apart from each other with the third pixel electrode 513 therebetween in a plan view. DC voltages transferred to the shielding patterns SHP apart from each other, respectively, may be different from each other. As an example, the first initialization voltage VINT may be transferred to one of the shielding patterns SHP, and the common voltage ELVSS may be transferred to the other shielding pattern SHP.

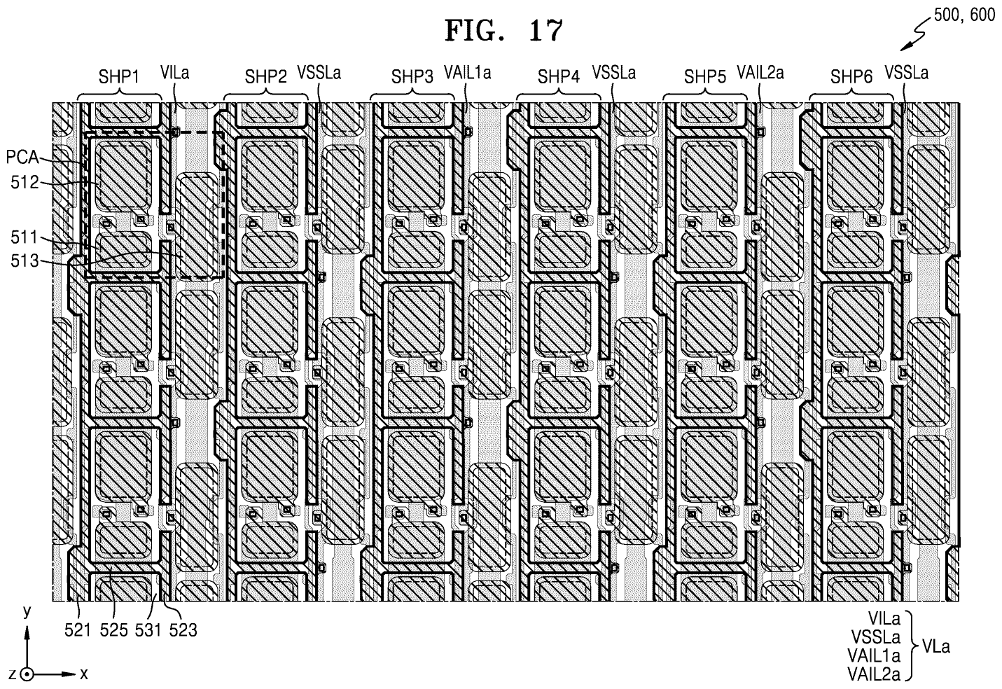

FIG. 17 is a schematic plan view of the shielding patterns SHP apart from each other according to an embodiment.

Referring to FIG. 17, the display panel 10 may include the first conductive layer 500 and the second conductive layer 600 disposed on the first conductive layer 500. The first conductive layer 500 may include the first data line DL1, the second data line DL2, the third data line DL3, the first driving voltage line PL1, the second driving voltage line PL2, and the auxiliary voltage lines VLa extending in the second direction (e.g., y direction). The second conductive layer 600 may include the first pixel electrode 511, the second pixel electrode 512, the third pixel electrode 513, and the shielding patterns SHP apart from each other in the first direction (e.g., x direction).

Each of the shielding patterns SHP may include the first portion 521 overlapping the first data line DL1, the second portion 523 overlapping the second data line DL2, and the first connection portion 525 connecting the first portion 521 to the second portion 523. The first portion 521, the second portion 523, the first connection portion 525, and the second connection portion 527 may be integrally connected to each other. The adjacent shielding patterns SHP may be apart from each other with the third pixel electrodes 513 therebetween.

As described with reference to FIG. 8, a voltage transferred by each of the auxiliary voltage lines VLa may have preset sequences of values that are repeated in the first direction (e.g., x direction). As an example, the auxiliary voltage lines VLa may be repeatedly disposed in the first direction (e.g., x direction) in the order of the first auxiliary initialization voltage line VILa, the auxiliary common voltage line VSSLa, the second-1 auxiliary initialization voltage line VAIL1a, the auxiliary common voltage line VSSLa, the second-2 auxiliary initialization voltage line VAIL2a, and the auxiliary common voltage line VSSLa.

Each of the shielding patterns SHP may be electrically connected to an adjacent auxiliary voltage line VLa through a contact hole. As an example, a first shielding pattern SHP1 may be electrically connected to the first auxiliary initialization voltage line VILa through contact holes, a third shielding pattern SHP3 may be electrically connected to the second-1 auxiliary initialization voltage line VAIL1a through contact holes, and a fifth shielding pattern SHP5 may be electrically connected to the second-2 auxiliary initialization voltage line VAIL2a through contact holes. Each of a second shielding pattern SHP2, a fourth shielding pattern SHP4, and a sixth shielding pattern SHP6 may be electrically connected to an adjacent auxiliary common voltage line VSSLa through contact holes. That is, a DC voltage transferred to each of the plurality of shielding patterns SHP may have preset sequences of values that are repeated in the first direction. Design of a DC voltage transferred to each of the shielding patterns SHP may be variously changed.

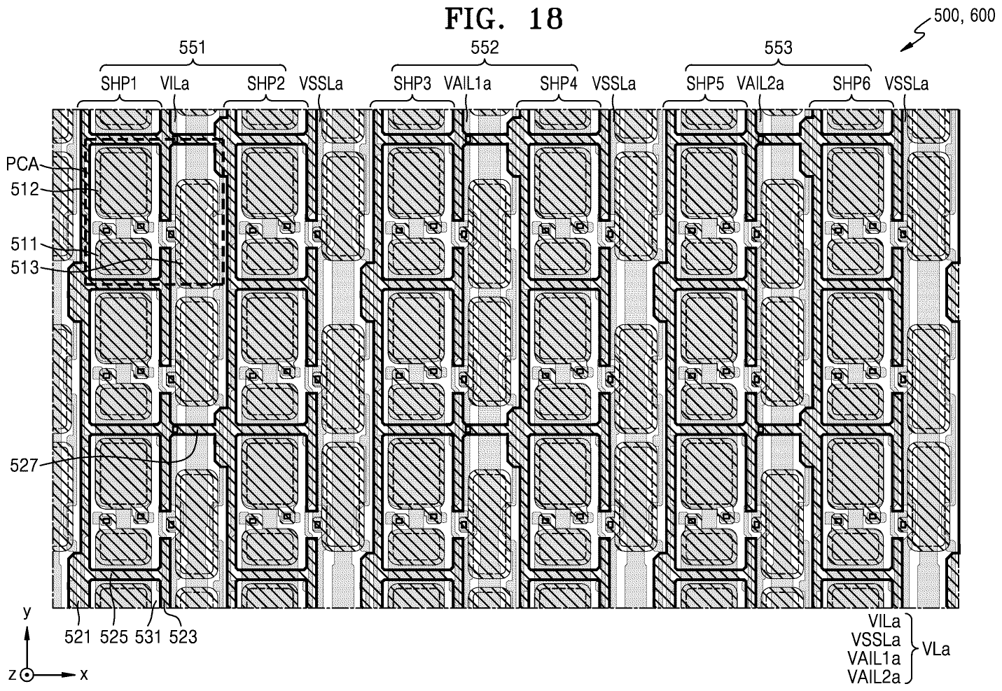

FIG. 18 is a schematic plan view of the mesh electrodes 520 apart from each other according to an embodiment.

Referring to FIG. 18, the display panel 10 may include the first conductive layer 500 and the second conductive layer 600 disposed on the first conductive layer 500. The first conductive layer 500 may include the first data line DL1, the second data line DL2, the third data line DL3, the first driving voltage line PL1, the second driving voltage line PL2, and the auxiliary voltage lines VLa extending in the second direction (e.g., y direction). The second conductive layer 600 may include the first pixel electrode 511, the second pixel electrode 512, the third pixel electrode 513, a first mesh electrode 551, a second mesh electrode 552, and a third mesh electrode 553.

The first mesh electrode 551, the second mesh electrode 552, and the third mesh electrode 553 may be disposed apart from each other in the first direction (e.g., x direction). Each of the first mesh electrode 551, the second mesh electrode 552, and the third mesh electrode 553 may include at least two shielding patterns SHP and the second connection portions 527 connecting the shielding patterns SHP. As an example, the first mesh electrode 551 may include the first shielding pattern SHP1, the second shielding pattern SHP2, and the second connection portions 527 connecting the first shielding pattern SHP1 to the second shielding pattern SHP2. The second mesh electrode 552 may include the third shielding pattern SHP3, the fourth shielding pattern SHP4, and the second connection portions 527 connecting the third shielding pattern SHP3 to the fourth shielding pattern SHP4. The third mesh electrode 553 may include the fifth shielding pattern SHP5, the sixth shielding pattern SHP6, and the second connection portions 527 connecting the fifth shielding pattern SHP5 to the sixth shielding pattern SHP6. Although it is shown in FIG. 18 that each of the first mesh electrode 551, the second mesh electrode 552, and the third mesh electrode 553 includes two shielding patterns SHP, the disclosure is not limited thereto. In another embodiment, the number of shielding patterns SHP included in the mesh electrodes may be different from each other.

Each of the shielding patterns SHP may include the first portion 521 overlapping the first data line DL1, the second portion 523 overlapping the second data line DL2, and the first connection portion 525 connecting the first portion 521 to the second portion 523. The first portion 521, the second portion 523, the first connection portion 525, and the second connection portion 527 included in one mesh electrode may be integrally connected to each other.

A voltage transferred by each of the auxiliary voltage lines VLa may have preset sequences of values that are repeated in the first direction (e.g., x direction). As an example, the auxiliary voltage lines VLa may be repeatedly disposed in the first direction (e.g., x direction) in the order of the first auxiliary initialization voltage line VILa, the auxiliary common voltage line VSSLa, the second-1 auxiliary initialization voltage line VAIL1a, the auxiliary common voltage line VSSLa, the second-2 auxiliary initialization voltage line VAIL2a, and the auxiliary common voltage line VSSLa.

Each of the first mesh electrode 551, the second mesh electrode 552, and the third mesh electrode 553 may be electrically connected to an adjacent auxiliary voltage line VLa through a contact hole. As an example, as shown in FIG. 18, the first mesh electrode 551 may be electrically connected to the first auxiliary initialization voltage line VILa through a contact hole, the second mesh electrode 552 may be electrically connected to the second-1 auxiliary initialization voltage line VAIL1a, and the third mesh electrode 553 may be electrically connected to the second-2 auxiliary initialization voltage line VAIL2a.

A DC voltage transferred to the mesh electrodes may have preset sequences of values that are repeated in the first direction (e.g., x direction). As an example, a DC voltage transferred to the mesh electrodes may be repeated in the order of the first initialization voltage VINT, the second-2 initialization voltage, and the second-2 initialization voltage. Design of a DC voltage transferred to the mesh electrodes may be variously changed. In an embodiment, the first mesh electrode 551 may be electrically connected to the auxiliary common voltage line VSSLa instead of the first auxiliary initialization voltage line VILa. Each of the mesh electrodes may be electrically connected to a voltage line vulnerable to a voltage drop.

The display panel 10 according to an embodiment may reduce coupling between the data lines and the opposite electrode by including the shielding patterns SHP transferring the DC voltage. In addition, the display panel 10 may reduce a drop of the DC voltage using the double connection structure of the shielding patterns SHP and the auxiliary voltage lines VLa.

According to an embodiment, the display panel configured to display high-quality images by reducing coupling between the electronic elements, and the electronic apparatus including the display panel may be implemented. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate including a display area and a peripheral area outside the display area;
a pixel circuit disposed in the display area and including a first sub-pixel circuit, a second sub-pixel circuit, and a third sub-pixel circuit adjacent to each other in a first direction;
a first insulating layer disposed on the pixel circuit;
a first conductive layer disposed on the first insulating layer and including a first data line connected to the first sub-pixel circuit, a second data line connected to the second sub-pixel circuit, and a third data line connected to the third sub-pixel circuit;
a second insulating layer disposed on the first conductive layer; and
a second conductive layer disposed on the second insulating layer and including a first pixel electrode connected to the first sub-pixel circuit, a second pixel electrode connected to the second sub-pixel circuit, a third pixel electrode connected to the third sub-pixel circuit, and a shielding pattern,
wherein the shielding pattern includes a first portion overlapping the first data line in a plan view, a second portion overlapping the second data line in the plan view, and a first connection portion connecting the first portion and the second portion to each other.

2. The display panel of claim 1, wherein the first portion, the second portion, and the first connection portion are integrally connected to each other.

3. The display panel of claim 1, wherein the first pixel electrode and the second pixel electrode are disposed between the first data line and the second data line in the plan view.

4. The display panel of claim 1, wherein the first data line and the second data line are symmetrically disposed around a virtual line passing between the first sub-pixel circuit and the second sub-pixel circuit and parallel to a second direction crossing the first direction.

5. The display panel of claim 1, wherein the first portion of the shielding pattern includes an extension portion overlapping the third data line, which is adjacent to the first data line.

6. The display panel of claim 1, wherein the first conductive layer further includes an auxiliary voltage line extending in a second direction crossing the first direction, and
the third data line and the auxiliary voltage line are symmetrically disposed around a virtual line passing through the third sub-pixel circuit and parallel to the second direction.

7. The display panel of claim 6, wherein the shielding pattern is connected to the auxiliary voltage line through a contact hole passing through the second insulating layer.

8. The display panel of claim 6, wherein the first conductive layer further includes: a first driving voltage line disposed between the first data line and the second data line; and a second driving voltage line disposed between the auxiliary voltage line and the third data line.

9. The display panel of claim 8, wherein the first pixel electrode and the second pixel electrode overlap the first driving voltage line, and the third pixel electrode overlaps the second driving voltage line in the plan view.

10. The display panel of claim 1, wherein the shielding pattern is provided in plurality,
the plurality of shielding patterns are apart from each other in the first direction, and
a voltage transferred to a first shielding pattern among the plurality of shielding patterns is different from a voltage transferred to a second shielding pattern among the plurality of shielding patterns.

11. The display panel of claim 10, wherein voltages transferred to the plurality of shielding patterns, respectively, have preset sequences of values that are repeated in the first direction.

12. The display panel of claim 1, wherein the shielding pattern is provided in plurality, and the second conductive layer further includes second connection portions connecting the plurality of shielding patterns to each other.

13. The display panel of claim 12, wherein the plurality of shielding patterns and the second connection portions are integrally connected to each other.

14. The display panel of claim 12, wherein the second conductive layer includes a plurality of mesh electrodes apart from each other in the first direction, and
each of the plurality of mesh electrodes includes at least two shielding patterns among the plurality of shielding patterns, and the second connection portions connecting the at least two shielding patterns.

15. The display panel of claim 14, wherein voltages transferred to the plurality of mesh electrodes, respectively, preset sequences of values that are repeated in the first direction.

16. An electronic apparatus comprising:
a display panel; and
a lower cover forming an exterior and defining, in a front surface thereof, an opening exposing a portion of the display panel,
wherein the display panel includes:
a substrate including a display area and a peripheral area outside the display area;
a pixel circuit disposed in the display area and including a first sub-pixel circuit, a second sub-pixel circuit, and a third sub-pixel circuit adjacent to each other in a first direction;
a first insulating layer disposed on the pixel circuit;
a first conductive layer disposed on the first insulating layer and including a first data line connected to the first sub-pixel circuit, a second data line connected to the second sub-pixel circuit, and a third data line connected to the third sub-pixel circuit;
a second insulating layer disposed on the first conductive layer; and
a second conductive layer disposed on the second insulating layer and including a first pixel electrode connected to the first sub-pixel circuit, a second pixel electrode connected to the second sub-pixel circuit, a third pixel electrode connected to the third sub-pixel circuit, and a shielding pattern,
wherein the shielding pattern includes a first portion overlapping the first data line in a plan view, a second portion overlapping the second data line in the plan view, and a first connection portion connecting the first portion and the second portion to each other.

17. The electronic apparatus of claim 16, wherein the first data line and the second data line are symmetrically disposed around a virtual line passing between the first sub-pixel circuit and the second sub-pixel circuit and parallel to a second direction crossing the first direction.

18. The electronic apparatus of claim 16, wherein the first portion of the shielding pattern includes an extension portion overlapping the third data line, which is adjacent to the first data line.

19. The electronic apparatus of claim 16, wherein the first conductive layer further includes: a first driving voltage line disposed between the first data line and the second data line; and a second driving voltage line disposed between the second data line and the third data line, and
the shielding pattern is connected to the first driving voltage line or the second driving voltage line through a contact hole passing through the second insulating layer.

20. The electronic apparatus of claim 16, wherein the shielding pattern is provided in plurality, and
the second conductive layer further includes second connection portions connecting the plurality of shielding patterns.
